(19) United States
(12) Patent Application Publication
(10) Pub. No.: US 2011/0193565 A9
(43) Pub. Date: Aug. 11, 2011

(54) DIELECTRICITY MEASUREMENT DEVICE

(76) Inventors: Dierk Schroeder, Hamburg (DE); Gottfried Von Bismarck, Hamburg (DE); Andreas Noack, Drage (DE)

(21) Appl. No.: 12/601,479

(22) PCT Filed: May 20, 2008
(86) PCT No.: PCT/EP08/04121

§ 371 Date: Nov. 23, 2009

(30) Foreign Application Priority Data
May 22, 2007 (DE) 10 2007 024 071.8
Jun. 6, 2007 (DE) 10 2007 026 646.6

(51) Int. Cl. G01R 27/04; G01R 27/26

(52) U.S. Cl. 324/637; 324/663

(57) ABSTRACT

A dielectricity measurement device and method for determining dielectric properties of portioned material of a capsule end package with the aid of an electrical field is described, where the device receives an electrically conductive package wall of the capsule end package as a component of the measurement arrangement and where the device maybe arranged into a series measurement device having several such dielectricity measurement devices.

The invention is in the technical field of measurement technology and concerns a dielectricity measurement device for determining dielectric properties of portioned material of a capsule end package with the aid of an electrical field, the dielectricity measurement device comprising a measurement chamber which is defined at least by an electrically conductive wall portion forming a first measurement means, and further concerns a series measurement device and a dielectricity measurement system. Furthermore the invention concerns a method for determining dielectric properties of portioned material of a capsule end package, comprising the steps of measuring dielectric properties of a measurement chamber of a dielectricity measurement device and of a package wall of the capsule end package without portioned material, measuring dielectric properties of the measurement chamber of the dielectricity measurement device and of the package wall of the capsule end package with portioned material, and calculating dielectric properties of the portioned material from the result of measuring dielectric properties of the measurement chamber of the dielectricity measurement device and of the package wall of the capsule end package without portioned material and the result of measuring dielectric properties of the measurement chamber of the dielectricity measurement device and of the package wall of the capsule end package with portioned material. Finally, the invention concerns a method for determining the mass/weight of portioned material of a capsule end package.

In order to ensure proper operation of industrial manufacturing and filling plants, it is usual to monitor the processes taking place there. For this purpose, single random samples are frequently taken in the production cycle and tested for the desired properties. Such random sample monitoring is, however, not sufficient if the desired parameters are to be maintained under all circumstances, which may be required for example in the manufacture of safety-relevant products or when filling with pharmaceutical products.

In such cases the product lines are monitored not just using random samples, but constantly instead, by for example continuously recording the relevant measurement variables in the flow of products or checking for each individual manufactured piece or each dispensed portion. Thus it is of the greatest importance, particularly if pharmaceutical preparations are dispensed in the intake quantity to be administered at any given time, to determine the exact quantity dispensed for each individual portion package after the filling operation, in order to ensure that only portion packages with a defined dosage of active ingredient can pass into circulation. The same applies to other technical fields, for example for the checking of individual packages of so-called one-day contact lenses and the like.

At present it is customary to package products or substances as portioned material. “Portioned material” in the present case refers to any substance or product which is manufactured for a single application with respect to its packaging, that is, in the case of pharmaceutical or cosmetic products for example by means of a pack as a single dose or, in the case of products, by means of a single or multiple pack (depending on how many individual pieces are needed in each case for a single application; in the case of gloves, for example, this is a double pack). Portioned materials of this kind are frequently sold in a capsule package, that is, in a sealed individual package of which the contents are protected from external influences by encapsulation. If the portioned material in this capsule package is made accessible to the end user, this package is preferably designed as a capsule end package which is routinely subject to particularly strict requirements with respect to labelling and handling, so that the possibility of wrongly using the contents by mistake is largely excluded.

The simplest parameter for determining the filling quantity of a portion package is usually the initial mass (the net mass) which is obtained for example as the difference between the mass of the filled portion package (the gross mass) and the mass of the empty portion package (the tare mass). Traditionally such determination of mass takes place by a gravimetric measurement method in which the material to be weighed is transferred to the pan of scales, and then, at the end of a period of time which is required for balancing out the pan, the mass value which is measured in each case is recorded. Balancing is required as a rule because the pan usually carries on oscillating after placing the material to be weighed on it, and so precise reading of the measured value is not possible.

As a result of the time required for balancing, a traditional gravimetric measurement method cannot easily be used with continuous or quasi-continuous monitoring of the filling quantity of a portion package because, in view of the high throughput speeds of industrial filling plants, this would result in a backlog and therefore not insignificant delays in the whole process. Moreover, when checking the filling of portion packages with pharmaceutical preparations using gravimetric methods, occasionally the sensitivity of the scales is too low for the use of traditional methods to be meaningful, as the mass of the package is frequently much greater than the mass of the substance to be packaged, so that the increase in mass upon filling is not indicated with sufficient accuracy.

To avoid a delay in the process cycle in general, usually contactless methods are used for mass determination with plants of this kind. If for example filling with dielectric (and therefore not or only poorly electrically conductive) substances is to be monitored, dielectricity measurement methods are used for this purpose, with which dielectric properties of the filled substance which can be converted to the respective mass of the substance after calibration of the measurement system are determined.

The dielectric conductivity & of a substance (epsilon symbol; also referred to as the permittivity) is obtained as the product of the dielectric constant ∈₀ (epsilon symbol with index “0”; also referred to as the permittivity of the vacuum or electric constant) and the dielectric function ∈ᵣ of the substance (epsilon symbol with index “r”; also referred to as the relative permittivity of the vacuum as well as—in isotropic media—the dielectric constant). The dielectric function ∈ᵣ, which as a rule depends on frequency, here constitutes a substance-specific quantity. This involves a complex quantity with the real part ∈′ (epsilon symbol with superscript mark) and the imaginary part ∈″ (epsilon symbol with superscript double mark) which is calculated from both portions as ∈ᵣ=∈′j∈″. The real and imaginary parts of a dielectric function and the resulting dielectric conductivity are described in general by the term “dielectric properties”.

Usually, in dielectricity measurement methods an effective dielectric function of the whole measurement arrangement including the substance to be tested is determined. From these measured values can be calculated the corresponding dielectric function of the substance to be tested, where the specific design of the measurement arrangement can be taken into consideration for example in the form of a reference value, for example by comparison of the measurement results with those of an empty measurement in which the measurement arrangement is tested without the substance to be tested.

In particular, capacitance measurements and microwave resonance measurements are important as dielectricity measurement methods for determining the mass of a substance. With capacitance measurements, the variation in capacitance of a measurement capacitor which occurs when the substance to be tested is introduced into the measurement chamber between two capacitor plates designed as measurement electrodes is recorded. The capacitance is for this purpose calculated for example from the current which is observed when a given measurement voltage signal is applied. Taking into consideration the dimensions of the measurement electrodes and the distance between them, the effective dielectric conductivity of the measurement chamber or measurement cell can be calculated in this case. By measurement of the capacitance, the dielectric function and hence the mass of the substance to be tested can be determined (single-quantity measurement). If it is necessary at the same time to determine the water content as well, in addition the loss angle can be detected (two-quantity measurement). A general example of a system for determining mass using a capacitive method of this kind is described in WO 01/44764.

With microwave resonance measurements, the variation in resonance behaviour of a microwave resonator which occurs when the substance to be tested is introduced into a measurement chamber designed as a cavity resonator is recorded. By means of a coupling electrode, microwave radiation is delivered to the measurement chamber and exits in another section of the microwave resonator by means of a further coupling electrode, the intensity of the exiting microwave radiation being determined. If a single measurement of this kind is carried out for different frequencies of the input microwave radiation, a microwave resonance spectrum with a resonance signal peak of which the spectral position and width depend on the dielectric function of the measurement chamber with the substance to be tested is obtained. The general principle of mass determination with the aid of a microwave resonance method is described for example in U.S. Pat. No. 5,554,935. Further examples of specific apparatus for using this method are described in EP 1 467 191 and in EP 1 634 041.

With dielectricity measurement methods too, there can be falsification of the measurement results if the substance is tested together with the portion package. For this reason it is proposed in WO 01/44764 to transfer the substance for measurement without a package to a section designed as a receiving chamber within the measurement chamber, and to take it out again after measurement. With liquid or powdered substances, however, there is a risk here that part of the substance will stick to the wall of the receiving chamber and stay in it on removal, so that the measurement result for this portion and for subsequent portions is sometimes considerably altered or even falsified as a result.

Furthermore, substances which can be separated after the fashion of individually packaged goods such as tablets, pellets or gelatine capsules as in the apparatus described in U.S. Pat. No. 5,554,935 and EP 1 467 191 can also be passed as a stream of separated products without packaging through the measurement chamber. However, these methods cannot be employed with those substances which cannot be separated into portions after the fashion of individually packaged goods, for example in the case of liquids and powders.

A measurement method that can be used for individually packaged substances as well as for liquids and powders is disclosed in EP 1 634 041, in which the portion package filled with the substance is introduced into the measurement chamber and subjected to a measurement of dielectric properties, followed by gravimetric analysis of the total mass of portion package and substance. After calibration of the measurement apparatus, the respective substance mass can be determined from the two measured values. However, a drawback of this method is the requirement of a gravimetric measurement cell and the associated delay and reduced accuracy in the case of substance quantities of which the mass is low compared with the mass of the portion package.

It is therefore an object of the present invention, for determining the mass of a portioned material, to provide a dielectricity measurement device which eliminates these drawbacks, which is particularly suitable for portioned material which is in the form of a powder, a liquid or in single-piece form in a capsule end package, and which in this case allows precise and easy determination of mass without using a gravimetric measurement device.

This object is achieved according to the invention by a device of the kind mentioned hereinbefore, in which the dielectricity measurement device has a receiving region which is designed to receive and position at least one electrically conductive package wall of the capsule end package, and which is designed to temporarily bring the package wall of the capsule end package which is received by the receiving region as a temporary measurement means into a measurement arrangement with the first measurement means. This construction ensures that the dielectricity measurement device always permits introduction of the portioned material to be measured together with at least part of the capsule end package, without gravimetric measurement devices being required for individual measurement.

The specific design thus allows very fast and also reliable determination of the mass of the portioned material, as the portioned material is always introduced together with the package wall of the capsule end package into the dielectricity measurement device and removed from it again without separate transfer of the portioned material being required.

As a result of the design of the dielectricity measurement device for receiving the capsule end package as an essential part of the measurement arrangement, a particularly simple construction for a dielectricity measurement device which can also withstand the high mechanical stresses in the case of a large number of individual measurements on different samples in rapid succession is possible too.

Thus by means of a dielectricity measurement device of this kind it is possible to determine dielectric properties, for example the dielectric conductivity, the dielectric function or parts of it, for example the real part and/or the imaginary part of these two quantities, measurement being carried out using an electrical field. This field can be an alternating electromagnetic field such as is for example generated by applying an a.c. voltage, or the field of electromagnetic radiation. Instead of an alternating field, the electrical field can of course be a quasistatic electrical field such as can be obtained for example by applying a d.c. voltage superimposed on a square wave voltage with a single voltage crossing, or a field having any trend in time, as long as this trend in time is defined or at least can be defined precisely.

Portioned material of a capsule end package serves as the material to be measured, of which the dielectric property is to be determined. Any substance or product which is prepared and adapted for a single application with respect to its packaging can be used as the portioned material, in particular pharmaceutical products in the form of tablets, granules or powders, liquids or the like, where these pharmaceutical products naturally can contain any active ingredients.

Any individual packages which have an electrically conductive package wall are possible as the capsule end package for the corresponding substances or products. The package wall referred to is a component of the capsule end package or only a section of a component of the capsule end package which separates the interior of the capsule end package adapted to receive the portioned material, from the region outside the capsule end package.

Usually, such capsule end packages reach the end user in a sealed state. Capsule end packages can be designed differently; thus they may be for example sealed bags, blister packs, bottles, ampoules or the like, which as a rule consist of two or more parts, rarely only one part, the parts being joined together by the usual techniques (for example by a glued joint, welded joint, clamped joint, pinned joint, crimped joint or the like) and so cause encapsulation of the portioned material enclosed therein. The joint is frequently not releasable without destruction, so that the package also serves as a seal proving originality. Traditional materials for capsule end packages are for example metals, polymeric plastics, paper, cardboard or glass. These are routinely used in the form of films or moulded bodies which are made of these materials or combinations of these materials, for example in the form of a laminate.

Bags frequently consist of two pieces of film welded together at the periphery, which are either made completely from polymeric plastics or made from laminates of the plastics with paper or metal foils. Ampoules and bottles as a rule consist of a plastic or glass moulded body which is melted or welded for ampoules, but for bottles is sealed with a second glass, plastic, metal or the like moulded piece which is designed as a closure and which can also have sealing elements, for example made of silicone or rubber.

A blister pack commonly has for example a receiving portion which is provided with depression and which is sealed with a closure portion which is glued, welded or fused to the receiving portion on one side. Particular embodiments of such packs have, instead of the closure portion, a second receiving portion also provided with depressions, so that here two receiving portions are joined together. Usually a receiving portion is made of plastic or a laminate of several plastics with each other or one plastic or several plastics with a metal foil, and a closure portion consists of a metal foil, a plastic film, a cardboard strip or a laminate of several plastics with each other or one or more plastics with a metal foil. Particularly common for pharmaceutical preparations are combinations of a receiving portion made of a polymer which is joined to a metal foil as a closure portion. All the usual suitable polymers are used as the polymers, for example polyethylene, polypropylene or polyvinyl chloride, and all the usual suitable metals are used as the metals, for example aluminium. Naturally blister packs can also have receiving portions which are made completely from a shaped metal sheet. As a rule both receiving portion and closure portion are thin-walled in a blister pack and have package walls which demarcate the pack from the outside.

The dielectricity measurement device itself is designed to receive at least part of the capsule end package for determining dielectric properties. The dielectricity measurement device has a measurement chamber which is arranged in its interior. This measurement chamber is demarcated from the outside by wall portions, the term wall portions referring to a function-related division of the wall of the measurement chamber; several of the wall portions may well in this case be constructed in one piece.

At least one wall portion is designed as an electrically conductive wall portion. The dielectricity measurement device also has a receiving region which is designed to receive and position at least one of the package walls of the capsule end package described above. The package wall here is an electrically conductive package wall as a component of the capsule end package; this package wall can here be a single element which is joined to further elements of the capsule end package, or an integral component of the capsule end package.

If therefore the package wall of the capsule end package is located in the receiving region and has been aligned in the receiving position (for which, if need be, the package wall can be temporarily fixed to the dielectricity measurement device), then the electrically conductive wall portion of the dielectricity measurement device and the package wall of the capsule end package define the measurement chamber. Preferably this takes place at mutually opposed and therefore spatially corresponding positions of the measurement chamber. It is particularly favourable here if the dielectricity measurement device is designed in such a way that the electrically conductive wall portion and the electrically conductive package wall of the capsule end package in the measurement arrangement have surfaces parallel to each other and at the same time opposed to each other, the field lines of the electrical field in the measurement chamber at the surfaces running perpendicularly to the surfaces. As the portioned material is close to the package wall, in this way a substantially homogeneous electrical field in the position of the portioned material is ensured, and hence particularly reliable measurement of the dielectric property of the portioned material in the measurement arrangement is possible.

According to the invention the dielectricity measurement device is designed to temporarily bring the package wall of the capsule end package received by the receiving region into a particular arrangement relative to the wall portion which allows measurement of dielectric properties and so constitutes the measurement arrangement.

For the measurement of dielectricity, the presence of both parts is absolutely necessary, that of the electrically conductive wall portion and that of the electrically conductive package wall. Consequently these two parts form measurement means: the electrically conductive wall portion of the dielectricity measurement device here forms the first measurement means, and the electrically conductive package wall of the capsule end package here forms—because this element is only temporarily introduced into the measurement apparatus and is removed again after measurement—the temporary measurement means.

As a result of the special design of the receiving region, the package wall of the capsule end package is designed relative to the measurement chamber in such a way that the portioned material is arranged within the measurement chamber of the dielectricity measurement device in relation to the package wall. Here it is particularly favourable if the dielectricity measurement device is designed in such a way that between the first measurement means and the temporary measurement means a space for the portioned material to be tested is designed as a portioned-material chamber, that is, an enclosed measurement chamber for the portioned material, which surrounds the portioned material to be measured.

In an advantageous embodiment the dielectricity measurement device as part of an electrical measurement capacitor for determining the dielectric property of portioned material of a capsule end package is constructed and designed to form the electrical measurement capacitor temporarily together with the temporary measurement means. Detection here is by customary known methods. Due to a construction of this kind, a particularly simple, reliable and cheap dielectricity measurement device is provided. It is sensible here if the temporary measurement means is supported by an additional support element, so that the package wall is mounted free from vibrations in the receiving region and the capacitance of the whole measurement arrangement therefore does not vary accidentally.

With this construction it is particularly advantageous if the first measurement means is designed as a first measurement electrode, and the dielectricity measurement device is further designed to receive the temporary measurement means as a second measurement electrode in such a way that the first measurement electrode and the second measurement electrode are electrically insulated from each other.

For this it is necessary to make an electrical connection to the electrically conductive package wall of the capsule end package. This is possible by all customary methods suitable for this purpose. Such a connection can here be by galvanic or capacitive connection. If for example the electrically conductive region of the package wall lies directly at the surface of the side face which is arranged outside the measurement chamber in the measurement arrangement, a signal wire of the dielectricity measurement device can be passed directly to the electrically conductive surface and joined to the latter for example by a clip end piece, a spring end piece or by means of a wire pressed against the surface for galvanic contact. The surface can here be arranged in any position on the package wall, for example on its front, back or edge, or in several of these positions.

If, however, only electrically non-conductive (and therefore insulating) parts of the surface of the package wall are arranged at the side face which is arranged outside the measurement chamber in the measurement arrangement, then direct galvanic contact of the conductive package wall by taking a signal wire to the surface is not possible. This is the case for example when the electrically conductive region of the package wall is covered on the outside, for example with an insulating plastic film or insulating plastic laminate layer. In this case for example galvanic contact can be made invasively, that is, at least partially destroying the capsule end package, by the fact that for example a pointed probe at the end of the signal wire is poked through the insulating plastic film and so makes electrically conductive direct contact with the electrically conductive region of the package wall.

Since with invasive measurements there is always a risk of damage to the encapsulation, the electrical connection can be made capacitively instead. A capacitive connection of the electrically conductive package wall of the capsule end package to the dielectricity measurement device of this kind can for example be provided by passing an electrically conductive region of the signal wire to the non-conductive surface of the package wall, without damaging the non-conductive region of the package wall. In this way an electrical connection is made without there being conductive galvanic contact at the same time.

By the capacitive connection it is possible to produce a connection with defined properties. This is particularly advantageous where other connection methods would lead to indefinite connections which may falsify the measurement results in a manner that cannot be reproduced. This can for example be a problem when the surface of the package wall is made of aluminium. On the upper side of aluminium, in air, a dense thin oxide layer forms, which prevents further corrosion as a passive layer. This passive layer itself is however electrically non-conductive, so that in air a galvanic connection to an aluminium surface is possible only with destruction of the passive layer. Contact of this kind would however be electrically indefinite. Instead, it may be sensible to coat the aluminium surface thinly with a non-conductive polymer, excluding air, for example with a polyester, to produce a surface which is defined in relation to capacitive and ohmic properties. An electrically conductive package wall which is coated non-conductively in this way can be temporarily connected by capacitive contact to the dielectricity measurement device. This capacitive connection can therefore be a defined non-contact as an electrical connection.

Necessary electrical insulation of the first measurement means from the temporary measurement means can be carried out by ordinary adapting steps; thus for example the contact face of the receiving region of the dielectricity measurement device, which in the measurement arrangement is in contact with the electrically conductive part of the package, can be electrically insulating. Moreover, naturally all other suitable measures are feasible, for example those in which the other wall portions which define the measurement chamber between the electrically conductive wall portion and the package wall are electrically insulating.

As an alternative to the design of the dielectricity measurement device for capacitive dielectricity measurement, the dielectricity measurement device can also be designed for microwave resonance dielectricity measurement. For this purpose it is an advantage if the dielectricity measurement device has a first coupling element for the input of microwave radiation into the measurement chamber and a second coupling element for the exit of microwave radiation from the measurement chamber, the dielectricity measurement device being designed as part of a microwave resonator for determining dielectric properties of portioned material of a capsule end package, and the dielectricity measurement device being designed to temporarily form the microwave resonator together with the temporary measurement means. In this way it is possible to obtain in a particularly simple manner dielectric properties of the portioned material itself which result from the shift of the resonance signal peak as a result of introducing the portioned material into the measurement chamber, and its dielectric loss (as the imaginary part of the dielectric function) which results from widening of the resonance signal peak and allows conclusions about the water content of the portioned material and the measurement chamber.

Using the first coupling element, microwave radiation is delivered to the measurement chamber. For recording one complete resonance curve, the frequency of the input microwave radiation within the relevant measurement region is successively varied, so that microwave radiation of different frequencies is delivered.

Using the second coupling element, the input microwave radiation which satisfies the condition of resonance is discharged from the measurement chamber and detected in the subsequent detection circuit using conventional methods.

Here, the first and second coupling elements are usually made separate from each other, for example the first coupling element as a first coupling aerial (first coupling probe) and the second coupling element as a second coupling aerial (second coupling probe) which is different to the first coupling element. But instead, the first and second coupling elements may be integrated, for example as a combined coupling electrode by means of which the microwave radiation is delivered to the measurement chamber and is also discharged again, as may be sensible for example for reflection measurements.

In this way it is possible to design the dielectricity measurement device as part of a microwave resonator for determining dielectric properties of portioned material of a capsule end package, the dielectricity measurement device then being designed to temporarily form the microwave resonator together with the temporary measurement means. This concerns first and foremost a design for receiving the package wall of the capsule end package, for which purpose all customary suitable adaptation methods and adaptation possibilities can be used.

It is particularly favourable here if the first measurement means is designed as a partial region of the inner wall of a cavity resonator and the dielectricity measurement device is designed to receive the temporary measurement means as a further partial region of the inner wall of the cavity resonator in such a way that the first measurement means and the temporary measurement means are electrically connected to each other by further partial regions of the inner wall of the cavity resonator, and so together with the further partial regions of the inner wall temporarily form the hollow conductor of the cavity resonator, that is, the closed hollow-conductor chamber with electrically conductive walls, which forms the resonator chamber of the microwave resonator. In this way the package wall forms part of the cavity resonator itself, so that the structure of the measurement arrangement is further simplified. But at the same time the reliability of measurement data is also increased, as the portioned material is introduced directly into the resonator chamber.

As the electrical conductivity of the inner wall of the cavity resonator is important for the formation of standing waves within the cavity resonator and hence also for the functionality of the resonator as a whole, the electrically conductive first measurement means and the electrically conductive temporary measurement means in the measurement arrangement should in each case be electrically connected to the remaining wall portions. This can be done in a customary suitable manner, for example using the methods described above to produce a galvanic connection or a capacitive connection.

Furthermore it is also possible to close the resonator by capacitively connected wall portions, by which means the connection of elements with non-conductive surfaces can be simplified.

Furthermore it is advantageous if the form of the first measurement means is adapted to the form of the temporary measurement means in such a way that the first measurement means is a short distance from the temporary measurement means on the one hand and from the surface of the portioned material introduced into the capsule end package on the other hand. As a result of the special adaptation of the receiving region of the dielectricity measurement device and the form of the capsule end package on the one hand and adaptation of the spatial form of the mutually opposed surfaces of the first measurement means and temporary measurement means on the other hand, a particularly high field strength of the electrical field is produced in the location where the portioned material is arranged, which results in a particularly strong influence of the portioned material on the resonance signal and so improves the precision of measurement.

It is also favourable if the dielectricity measurement device in the measurement chamber at least close to the first measurement means has a dielectric resonator packing with a high dielectric constant. The resonator packing in the present case refers to an element which is located in the resonance chamber of the measurement arrangement, and which therefore is arranged within the cavity resonator, and of which the dielectric property influences the measurement result as a whole in a controlled manner. Due to this design, the effective dielectric function of the measurement chamber is modified to the effect that the shift of the resulting resonance signal in case of relatively small dimensions of the microwave resonator leads to a signal position comparable to that of a larger resonator. In this way it is possible to reduce the dimensions of the dielectricity measurement device while the quality of measurement remains the same. A resonator packing of this kind can here be connected to one or more components of the measurement arrangement, for example to a wall portion of the dielectricity measurement device, or be made separate from this.

Here it is particularly favourable if the form of the resonator packing is adapted in such a way that the end section of the resonator packing arranged closest to the temporary measurement means is a short distance from the temporary measurement means on the one hand and from the surface of the portioned material introduced into the capsule end package on the other hand. A particularly high field strength is also generated at the position of the portioned material by a design of this kind.

A dielectricity measurement device designed as a microwave resonator is particularly advantageous if the measurement chamber comprises, as the boundary, side wall portions and the first measurement means, which are electrically connected to each other in the measurement arrangement, the side wall portions being designed as a peripherally closed wall frame with a first bottom opening and a second bottom opening, and the first measurement means and a first bottom opening of the side wall frame being movable relative to each other and designed to temporarily form the measurement chamber by at least partial form-locking. In this way it is possible to measure different portioned material in rapid succession one after the other.

This includes the measurement chamber being laterally bounded by wall portions which form a cohesive frame, the wall frame, which is thus peripherally closed (that is, on the outsides of all edges).

The wall frame has, centrally in its two bottom sides (the two bottom surfaces), through-openings, the first and second bottom openings, which are aligned with each other and connected to each other. The connection between these openings forms the measurement chamber and hence also the resonator chamber. As a boundary of the measurement chamber the latter can have, in addition to the wall portions at the first bottom opening, the first measurement means. The first measurement means is however movable relative to the wall frame, so that the first measurement means can be moved to the first bottom opening of the wall frame, or the wall frame with its first bottom opening can be moved to the first measurement means, so that the first measurement means closes the first bottom opening of the wall frame in form-locking relationship and defines the measurement chamber at the bottom, at least temporarily forming the measurement chamber. Here too it is advantageous if the boundary portions of the measurement chamber are electrically conductively connected to each other.

Due to the fact that the wall frame and the first measurement means are movable relative to each other, it is possible to make one of these two units stationary and the other movable, so that the different parts within a short time can be assembled into a temporarily existing dielectricity measurement device and separated again after measurement, which can bring about simplification of automation of the measurement method. This is the case particularly if the dielectricity measurement device comprises a movable cassette element which has a plurality of side wall frames which are connected to each other, and if the first measurement means is designed as part of a stationary electrically conductive shoe, the cassette element and the shoe being designed to temporarily form the measurement chamber from the first measurement means and each of the plurality of wall frames by movement of the cassette element past the portion of the shoe designed as the first measurement means, in each case successively.

In this case the first measurement means is therefore designed as a stationary electrically conductive shoe (or at least as part of such a shoe) past which a movable side wall frame is moved and so for a short time forms the measurement chamber.

To further improve the method, a plurality of side wall frames are connected to each other over a closed line. The succession of wall frames here forms a cassette element in which the wall frames are arranged rigidly (for example in the form of a circular arrangement of the wall frames within the cassette element) or flexibly (for example on a supporting guide belt).

By using a cassette element with a plurality of wall frames, upon movement of the cassette element past the stationary shoe, not just one, but a plurality of measurement chambers one after the other are formed temporarily.

It is particularly advantageous here for example if the first measurement means is formed from the cylinder arc-shaped side surface of the shoe, and if the cassette element is mounted rotatably and has two parallel circular rings which are spaced apart from each other by a plurality of radially mounted intermediate frame walls in such a way that in each case two adjacent intermediate frame walls and two parallel circular ring segments are connected electrically conductively and so form the wall frame, and two adjacent wall frames in each case have a common intermediate frame wall, the shoe being arranged relative to the cassette element in such a way that the shoe fits electrically conductively between the two circular rings in the region of the first bottom openings of the wall frames, so that upon rotation of the cassette element the dielectricity measurement device is formed temporarily, and the wall frames of the cassette element having second bottom openings to the outside, and the dielectricity measurement device being designed in such a way that temporary measurement means and the second bottom openings move closer together and with the latter are brought temporarily into an electrically conductive measurement arrangement.

Due to the rotatable mounting of the cassette element, the latter can easily be moved past the stationary shoe. If the wall frames in the cassette element are arranged in a circle, the sequence of individual measurements is still further simplified. Here, the cassette element has two parallel circular rings which are spaced apart from each other by a plurality of radially mounted intermediate frame walls. Each wall frame is here formed by two adjacent intermediate frame walls and one segment on each circular ring, the circular ring segments being arranged with their main extent parallel to each other. Circular ring segments and intermediate frame walls are in each case connected electrically conductively. For further simplification the wall frames directly follow each other within the cassette element, that is, without a gap in between, so that two adjacent wall frames in each case have a common intermediate frame wall and circular ring segment pairs adjoining each other in pairs.

The openings in the wall frames thus run radially to the circular ring, so that some of the openings can be closed by the first measurement means when the first measurement means has a cylinder arc-shaped side surface of the shoe. The shoe is here arranged relative to the cassette element in such a way that its cylinder arc-shaped side surface in the region of the first bottom openings of the wall frames fits electrically conductively between the two circular rings, in which case electrical contact can be for example through the circular rings themselves or through additional sliding contacts or slip rings. On rotation of the cassette element, the dielectricity measurement device is therefore formed temporarily each time. The radial second opening of the wall frames is adapted so that the temporary measurement means in the process are applied to this second bottom opening and also cover it electrically conductively, so that in combination with closure of the first bottom opening by the first measurement means as a whole the measurement arrangement is formed.

To simplify the device it is sensible that the shoe is arranged at the inner opening of the circular ring-shaped cassette element, and so the second bottom opening forms the outer radial opening of the circular ring-shaped cassette element. Naturally the dielectricity measurement device can also be constructed in such a way that the shoe is arranged at the outer radial opening of the circular cassette element, and the inner radial openings form the second bottom openings of the wall frames.

In relation to the electrically conductive package wall, the portioned material in the measurement arrangement must in this embodiment too be oriented towards the measurement chamber of the dielectricity measurement device. If the package wall of the capsule end package is in this case open to the dielectricity measurement device and is therefore supplied not yet encapsulated, then it is necessary for powdered or liquid portioned material to be arranged on the upper side of the package wall. If also the region of the package wall under the portioned material is an electrically conductive region of the package wall, then this means that the package wall is supplied with the portioned material to the dielectricity measurement device from below, and consequently the cassette element in the temporarily formed measurement arrangement is arranged over the package wall, for example on the lower section of the cassette element. This is a particularly simple and therefore advantageous design.

If, on the other hand, the capsule end package is already closed and therefore encapsulated during measurement, so that the portioned material cannot fall out, then the package wall can be supplied to the dielectricity measurement device from the other side, as long as in the measurement arrangement the portioned material is arranged within the measurement chamber. This means that the capsule end package can be delivered to the dielectricity measurement device at an upper section of the cassette element as well, that is, “overhead” or “in suspension”, if the electrically conductive package wall is oriented radially outwards and the encapsulated portioned material is therefore oriented radially inwards.

As a further improvement to this construction, the cylinder arc-shaped side surface of the shoe can also have depressions in which the first and second coupling elements are received electrically insulated by the shoe. In this way the coupling elements are protected from mechanical damage even at high speeds of rotation of the cassette element.

Moreover the present invention offers a series measurement device for successively determining dielectric properties of portioned material of a plurality of capsule end packages, the series measurement device comprising a plurality of dielectricity measurement devices according to the invention. The first measurement means of the dielectricity measurement devices are in this case arranged on a first combination element which is designed to receive a plurality of temporary measurement means. With a series measurement device of this kind it is possible to check a plurality of capsule end packages within a short time and so carry out particularly easy monitoring of a filling process.

This is possible in particular by arrangement of a plurality of dielectricity measurement devices on a single element, the first combination element. Thus for example several dielectricity measurement devices can be actuated together by means of the first combination element, each individual dielectricity measurement device being brought into a measurement arrangement with one package wall of a capsule end package. In this way for example several measurement arrangements can be produced simultaneously and therefore parallel measurement can be carried out on several capsule end packages.

Here, the first combination element can have a plurality of dielectricity measurement devices arranged adjacent (and hence parallel) to each other, so that with a single actuating action a movement of the first combination element towards the package walls (or, as a further possibility of a movement directed relative to each other conversely, a movement of the package walls towards the first combination element) can be brought about. In this case several measurement arrangements are formed and therefore also several measurements are performed in parallel. In addition or instead, the first combination element can have several dielectricity measurement devices arranged one behind the other. As a result, depending on the specific design, likewise several individual measurements can be performed simultaneously, or the process of a sequential multiple measurement in which several package walls can be tested successively can be simplified.

It is particularly advantageous here if this series measurement device further comprises a second combination element which is designed as a carrier portion for a plurality of temporary measurement means, the first combination element and the second combination element being designed for a movement directed relative to each other. In this way the performance of a plurality of measurements is further simplified. Thus by using a single second combination element which receives a plurality of package walls of capsule end packages as the carrier portion, with easy handling of a single element at the same time a plurality of package walls can be moved and transferred to a measurement arrangement.

The carrier portion can have any design for this purpose. Thus for example this can involve carrying sections with depressions for receiving capsule end packages. The carrying sections can for example contain rows of several such depressions in parallel alignment which in each case can be brought simultaneously into measurement arrangements. Moreover, the carrier portion can have a plurality of such rows one behind the other. This can be obtained for example by the fact that the carrying sections are arranged endlessly on one element or chain element. But instead, other arrangements are possible too, for example the arrangement of a fixed number of carrying sections one behind the other, for example in the form of a palletlike holder or the like.

It is favourable if the first combination element is designed as a matrix frame in which the first measurement means of the plurality of first measurement means are arranged flat in each case adjacent to each other. A matrix frame of this kind can have a one-dimensional or two-dimensional arrangement of the individual dielectricity measurement devices, so that by a single movement of the matrix frame either in the case of a one-dimensional arrangement one row of parallel package walls, or in the case of a two-dimensional arrangement several rows of parallel package walls, can be tested simultaneously. At its simplest, the movement of the matrix frame involves lowering of the matrix frame onto package walls which are being moved past it underneath. The process of measurement can be greatly simplified by such a design.

It may also be favourable if the first combination element is designed as a roller frame in which the first measurement means of the plurality of first measurement means are arranged in each case adjacent to each other on the shell of a cylinder roller. Here too, it is possible for several dielectricity measurement devices to be arranged parallel to each other on the shell, so that several measurements are performed simultaneously.

This likewise affords the advantage that, due to the cylinder symmetry, frequent up and down movement of the first combination element is not necessary. Instead, the roller-like first cornbination element can roll continuously over the surface of the package walls, while the individual dielectricity measurement devices are pressed against the package walls. As a result, the mechanical elements are exposed to only slight wear and the measurement time can also be shortened drastically.

Further, the present invention provides a dielectricity measurement system which comprises one of the dielectricity measurement devices described above and at least one electrically conductive package wall of a capsule end package. Due to the extremely advantageous design in the measurement arrangement of this measurement system, the advantages already described above are accomplished.

According to a further aspect of the present invention, a method for determining dielectric properties of portioned material of a capsule end package is proposed, comprising the steps of measuring dielectric properties of a measurement chamber of a dielectricity measurement device and of a package wall of the capsule end package with portioned material, and calculating dielectric properties of the portioned material from the result of measuring dielectric properties of the measurement chamber of the dielectricity measurement device and of the package wall of the capsule end package with portioned material, dielectric properties of the measurement chamber of the dielectricity measurement device and of the package wall of the capsule end package without portioned material being measured with a dielectricity measurement device which comprises one of the dielectricity measurement devices described above and a package wall of the capsule end package electrically connected to the latter temporarily. For this purpose, before measurement of dielectric properties of the measurement chamber of the dielectricity measurement device and of the package wall of the capsule end package with portioned material, at least the following steps are performed: the portioned material is transferred to a portioned-material region of the package wall of the capsule end package, the package wall of the capsule end package with the portioned material is introduced into the dielectricity measurement device, and at least one electrically conductive portion of the package wall of the capsule end package is electrically connected to the dielectricity measurement device, as a result of which the dielectricity measurement device and the package wall of the capsule end package are temporarily brought into a measurement arrangement, and after measuring dielectric properties of the measurement chamber of the dielectricity measurement device and of the package wall of the capsule end package with portioned material, the package wall of the capsule end package with the portioned material being taken from the dielectricity measurement device. Compared with the methods known up to now, this affords the opportunity to determine dielectric properties of portioned material of different nature, structure and form in a simple manner and with high reliability, even determination with portioned material in a capsule end package which is already encapsulated being possible.

For this method, therefore, dielectric properties of the measurement chamber of the dielectricity measurement device and of the package wall of the capsule end package are measured together with the portioned material. Dielectric properties of the portioned material are calculated from the result of this measurement.

By this method it is on the one hand possible to obtain information on dielectric properties of package walls of a plurality of capsule end packages provided with portioned material relative to each other, by performing the measurements on the package walls successively and comparing with each other the values determined in this way, for example with respect to deviations from a mean value or target value.

On the other hand, by the method according to the invention dielectric properties can also be determined as absolute quantities. If, for example, the package wall is a product produced with high reproducibility, it may be sufficient before the first measurement row to measure a single one of these package walls without portioned material in the dielectricity measurement device as a basic value, and to use the basic value determined in this way for initial calibration of the measurement apparatus. After such initial calibration, dielectric properties of the portioned material can now be determined as absolute quantities by the method described above.

As an extension of the method according to the invention, for absolute determination of dielectric properties it is advantageous if, before transfer of the portioned material to the portioned-material region of the package wall of the capsule end package, dielectric properties of the measurement chamber of the dielectricity measurement device and of the package wall of the capsule end package without portioned material are measured, and if the calculation of dielectric properties of the portioned material takes place by calculating them from the result of measuring dielectric properties of the measurement chamber of the dielectricity measurement device and of the package wall of the capsule end package with portioned material and the result of measuring dielectric properties of the measurement chamber of the dielectricity measurement device and of the package wall of the capsule end package without portioned material. In this way, for each package wall to be tested, before adding the portioned material it is introduced into a dielectricity measurement device and measured individually, so that a reference value of the package wall without portioned material is obtained. The dielectricity measurement device of this reference measurement can in this case be the same dielectricity measurement device as the first dielectricity measurement device which is provided for the actual measurement, or a second dielectricity measurement device different to the latter, which is advantageously similar in structure to the first dielectricity measurement device. The reference value obtained in this way corresponds as a specific and therefore exact blind value to the dielectric properties of the whole dielectricity measurement arrangement for each individual capsule end package. This reference value is taken into consideration when calculating the dielectric properties of the portioned material and so allows high-precision determination of dielectric properties of portioned material. By this method package walls which are made with a high manufacturing tolerance can be used as well.

As a special feature, for this method not only is the dielectricity measurement device of the kind described above used, in which the package wall of the capsule end package temporarily forms a substantial component of the measurement arrangement which is essential for measurement, but the actual measurement is also performed on portioned material which has already been transferred to a region of the package wall provided specially for this purpose, to the portioned-material region of the package wall. For measurement, the portioned material is introduced together with the package wall into the dielectricity measurement device where the actual measurement takes place in situ and the portioned material at the same time is located on the package wall. For measurement, the package wall or at least an electrically conductive portion thereof is electrically connected to the dielectricity measurement device, as a result of which the dielectricity measurement device and the package wall of the capsule end package are temporarily transferred to the actual measurement arrangement. After dielectricity measurement, the package wall with the portioned material is finally taken away from the measurement arrangement again.

Here, the capsule end package can be sealed and so form the encapsulation, by joining a receiving portion of the capsule end package to a closure portion of the capsule end package before the capsule end package is introduced with the portioned material into the measurement chamber, or after the capsule end package with the portioned material has been taken out of the measurement chamber, at least part of the receiving portion and/or at least part of the closure portion forming the package wall of the capsule end package. As a result, the portioned material—for example, in the case of particularly delicate portioned material—can be either already encapsulated in the capsule end package before the actual measurement and so protected, or after the actual measuring step, which is advantageous for example when the capsule end package must necessarily consist of a metal-containing receiving portion and a metal-containing closure portion, which would make it impossible to determine dielectric properties of the contents of the package.

It is favourable here if the measurement of dielectric properties is carried out using a measurement capacitor in the dielectricity measurement device described above as such. Alternatively, the measurement of dielectric properties can be performed—as described above—using a microwave resonator as the dielectricity measurement device.

A method which proved to be particularly advantageous is one in which the measurement of dielectric properties is carried out using the dielectricity measurement device with the wall frames described above, the first measurement means and the first bottom opening of the wall frame being moved relative to each other and so temporarily forming the dielectricity measurement device as soon as the first bottom opening is arranged directly at the first measurement means, and furthermore the package wall of the capsule end package and the second bottom opening being moved closer together and temporarily brought into a measurement arrangement on contact. This method allows time-saving successive measurement of dielectric properties on a plurality of different portioned material.

This is achieved by a relative movement of the first measurement means in relation to the first bottom opening of the wall frame, temporarily forming the dielectricity measurement device as long as the first measurement means is temporarily positioned directly at the first bottom opening. A measurement arrangement is formed if, in addition, the package wall and the second bottom opening are moved close together and in this position electrically connected to each other.

With this semicontinuous measurement method, it proved to be extremely favourable if the measurement of dielectric properties is carried out using the dielectricity measurement device with the cassette element described above in the form of a single measurement, in which the package wall of a capsule end package is moved up to a second bottom opening of the wall frame in the revolving cassette element and brought into electrical contact with the latter, the package wall together with the cassette element is moved along the stationary shoe at the same speed of rotation as the cassette element, forming a dielectricity measurement device by contact-locking between the shoe and the first bottom opening of the wall frame in the cassette element, measurement of dielectric properties is carried out, and the package wall of the capsule end package is released from the second bottom opening of the wall frame in the revolving cassette element and moved away from the latter, a plurality of individual measurements being performed successively on rotation of the cassette element according to the number of wall frames present therein.

For each individual measurement, here the package wall of a capsule end package is moved up to a second bottom opening of the wall frame in the revolving cassette element and brought into electrical contact with the latter. In this close-up position the package wall moves together with the cassette element at the same speed of rotation as the cassette element in a direction towards the stationary shoe. If the first bottom opening of the wall frame of the cassette element comes into electrical contact with the shoe, the measurement arrangement is foamed and the individual measurement is performed. At the end of the measurement the cassette element with the package wall is moved away from the stationary shoe, and then the package wall is removed from the second bottom opening of the wall frame. As a result of the circular ring-shaped arrangement of the wall frames within the cassette element, at the same time in the case of wall frames which spatially follow this wall frame, the same steps are performed with different package walls after a time lag. In general, this results in semicontinuous measurement of dielectric properties of a sequence of different measurement arrangements, the number of which per rotation of the cassette element corresponds to the number of individual wall frames present in the cassette element.

Advantageously, this method is carried out as a series measurement method in which measurement is performed as a series measurement with one of the series measurement devices described above, package walls of the capsule end package being moved to the first combination element and the first combination element being brought into contact with the package walls of the capsule end packages, with the result that one dielectricity measurement device of the series measurement device with one package wall in the partial region of the carrier portion is temporarily brought into a measurement arrangement. Thus by a movement of the first combination element to the package walls or by a movement of the package walls to the first combination element, one package wall and one dielectricity measurement device of the series measurement device, each, can be brought into a measurement arrangement. By using the first combination element, several individual measurements can now be performed simultaneously and/or the time interval between two successive measurements can be shortened, so that the expenditure required for a single measurement is reduced.

Here it is particularly advantageous if with the method in addition to the first combination element a second combination element is used, on which a plurality of package walls are arranged as a grid, and the package walls of the capsule end packages are introduced with the portioned material into the dielectricity measurement device, and in which the second combination element with the package walls of the capsule end packages is moved past the first combination element, and meanwhile in a partial region of the second combination element the package walls and the second combination element are brought into contact with the first combination element, by the fact that the second combination element is moved at least in one section up to the partial region of the second combination element. As a result, particularly easy handling of a large number of package walls is possible, which also greatly simplifies the simultaneous measurement of several package walls with or without portioned material.

Thus it is for example an advantage if this method is performed by means of a series measurement device with a matrix frame as the first combination element, in which the matrix frame can be lowered onto the partial region of the second combination element. As a result, a plurality of dielectricity measurement devices of the series measurement device and a plurality of package walls in the partial region of the carrier portion can simultaneously be brought temporarily into measurement arrangements, and so several measurements can be performed in parallel and therefore simultaneously.

Instead, the method can also be performed by means of a series measurement device with a roller frame as the first combination element which contacts the second combination element and is rolled over the second combination element with the package walls in such a way that a plurality of dielectricity measurement devices of the series measurement device and a plurality of package walls in the partial region of the carrier portion are temporarily brought into measurement arrangements. As a result it is particularly easy to perform several individual measurements one after the other, as the first combination element does not have to be lifted off the package walls each time, but instead is lifted off the upper side of the package walls by the rotary movement of the roller. At the same time dielectricity measurement devices which are located behind the raised dielectricity measurement device in the circumferential direction of the roller frame come into contact with subsequent package walls and so form new measurement arrangements. Due to this conduct of the method, the process of the individual measurements is therefore likewise greatly shortened and also the measurement apparatus due to the continuous rolling movement of the roller frame is in general subjected to smaller mechanical loads than in the case of discontinuous movements of the first combination element towards and away from the package walls.

Also favourable is a series measurement device in which a dielectricity measurement device is arranged movably and designed to be moved, in a movement which is directed towards a package wall of a capsule end package provided with portioned material, to the package wall, in order to form the measurement arrangement, in order then to be guided at the package wall at the same speed as the package wall (or at least substantially the same speed) parallel to this package wall (or at least substantially parallel) and finally in a movement which is directed away from the package wall provided with portioned material, guided away from the package wall. Such a design of the series measurement device affords the advantage that a plurality of capsule end packages can be measured one after the other in quick succession, in which case this can already be achieved with a single dielectricity measurement device, by contrast with the previous practical example.

The movement of the dielectricity measurement device itself can be different here, and so for example proceed in an irregular curve or in individual straight sections which are in each case joined by deflection points. However, to minimise the mechanical load occurring due to the movement of the dielectricity measurement device, it is an advantage if the dielectricity measurement device is moved in a regular curved path towards and away from the capsule end package. These paths can have any shape, for example circular paths or elliptical paths. In the latter case, it is particularly favourable if it is an ellipse of which the major axis is arranged at least substantially parallel to the side section of the dielectricity measurement device which is temporarily connected to the package wall of the capsule end package.

Likewise it is an advantage if the package walls of the capsule end packages are moved past the dielectricity measurement device on a supporting carrier element, the carrier element being in each case adapted to receive the package walls which are provided with the portioned material. If for example the package walls are package trays designed as depressions, the carrier element can for example have recesses which are arranged in one or more rows one behind the other for receiving the package trays. The dielectricity measurement devices used in this case can be all dielectricity measurement devices according to the invention, for example those in the form of a measurement capacitor or a cavity resonator. Also several dielectricity measurement devices can be provided parallel to each other in the series measurement device.

With a series measurement device of this kind, a measurement is performed by moving the package walls, which are arranged one behind the other and provided with portioned material, at a constant speed one after the other past the dielectricity measurement device. The dielectricity measurement device is in this case moved in front of a central measurement point towards a package wall, as a result of which, just before the measurement point, the measurement arrangement is formed. The dielectricity measurement device is moved in the measurement arrangement at constant and at least substantially the same speed as the package wall in the same direction as the package wall past the measurement point, and measurement is performed in this time. Behind the measurement point the dielectricity measurement device is moved away from the package wall and returned to the initial position in front of the measurement point, in order to be able to again form a measurement arrangement with the next package wall in the subsequent measurement cycle.

Further, the invention provides a series measurement device for successively determining dielectric properties of portioned material of a plurality of capsule end packages, which has at least one of the dielectricity measurement devices described above in a fixed position and is designed for continuous movement of capsule end packages past the dielectricity measurement device, the first measurement means being temporarily brought into a plurality of measurement arrangements successively with the plurality of temporary measurement means of the capsule end packages as a result of the movement past. In this way increased precision of measurement can be obtained, as the dielectricity measurement device is constantly in a precisely defined stationary position and the measurement arrangements are each formed by the passage of the capsule end packages. The capsule end packages can in this case be arranged for example in the form of an endless blister belt, a blister strip or the like, making it possible to move them successively past the rigid dielectricity measurement device.

In this case it is favourable if the side section of the dielectricity measurement device, which is oriented towards the capsule end package in the respective measurement arrangement, is adapted for passage of the capsule end packages such that the dielectricity measurement device and a package wall of the respective capsule end package with portioned material form at least temporarily a closed measurement chamber. This can take place for example by a flat design of the corresponding side of the dielectricity measurement device or by a convexly sealing bead which is arranged round the opening of the measurement chamber on the dielectricity measurement device side. The capsule end packages are in this case moved past the dielectricity measurement device in such a way that the measurement chamber is closed continuously, for instance by moving the capsule end packages past the dielectricity measurement device so as to fit snugly in planar relationship or are moved on a curved path up to the dielectricity measurement device, moved flat past it at the location of the measurement chamber and then moved on a curved path away from it again.

With such a design too, the package walls of the capsule end packages can be moved on a suitable supporting carrier element past the dielectricity measurement device. Further, all dielectricity measurement devices according to the invention are possible as the dielectricity measurement device, for example those in the form of a measurement capacitor or in the form of a cavity resonator. Also several dielectricity measurement devices can be provided parallel to each other in the series measurement device.

A particularly advantageous development of this series measurement device can be used in a method which is designed as a series measurement method. Measurement takes place by moving a plurality of capsule end packages past the dielectricity measurement device in such a way that the first measurement means with the plurality of temporary measurement means of the capsule end packages is successively brought in each case temporarily into a plurality of measurement arrangements and moved away from the respective measurement arrangement. During passage, dielectric properties of the measurement chamber of the dielectricity measurement device and of the respective package wall of the capsule end package with portioned material are measured continuously. The signal which shows a maximum deviation from a reference signal is defined as the measured value for the respective capsule end package. The reference signal is in this case recorded during passage of the capsule end packages at the point in time when there is no capsule end package with portioned material in the measurement arrangement, and therefore when the opening of the measurement chamber of the dielectricity measurement device is defined by a section of the package wall of a capsule end package which has no depression for receiving the portioned material, and which therefore is for example of flat design.

A method of this kind enables particularly high precision of measurement because, due to continuous detection, the signal with the maximum deviation in each case can be determined. Thus it may otherwise be problematic that, in the case of different individual measurements within the scope of a series measurement, the package wall of the capsule end package with the portioned material does not occupy the exact spatial arrangement relative to the dielectricity measurement device which would be necessary to ensure reproducibility of measurement. This may be important particularly in case of irregular design of the depression of a capsule end package provided for receiving the portioned material. Exact positioning of this kind can usually be obtained technically only at high cost. This exact alignment can be dispensed with because, according to the invention—while the package wall of the capsule end package is moved past the dielectricity measurement device—there will be an optimum arrangement relative to each other. This is detected on continuous recording of the signals and determined from the maximum deviation from the reference signal.

Lastly, the invention provides a method for determining the mass of portioned material of a capsule end package, comprising the steps of determining the dielectric properties of comparative portioned material of known mass by one of the methods described above; determining dielectric properties of the portioned material by the same method; calculating the mass from the results of determining dielectric properties of the comparative portioned material and of determining dielectric properties of the portioned material. For this measurement, for once-only adaptation of the dielectricity measurement device to the substance to be tested it is necessary for calibration to be carried out with a comparative portioned material which had approximately the same composition as the portioned material to be tested and of which the mass is known in addition (for example defined as a mass standard or using an already calibrated mass determining device).

In a further favourable embodiment of the method according to the invention for determining mass, the determination of dielectric properties comprises in each case determination of the frequency of the resonance peak of microwaves when one of the microwave resonator dielectricity measurement devices described above is used as the dielectricity measurement device and when a corresponding microwave resonance method is used as the method for determining dielectric properties of the portioned material. As a result it is possible after identification of the frequency of the microwave signal of maximum intensity to obtain the real part of the dielectric function merely from this value and so determine the mass of the portioned material, greatly simplifying signal processing by the fact that processing is limited to just this frequency and the rest of the frequency spectrum can be important only for further determining operations.

In the case of a high water content of the portioned material or a high moisture content in the measurement chamber, it may also be sensible if, in addition to the frequency of the resonance peak of the microwaves, the determination of dielectric properties further comprises determination of the attenuation of the resonance signal of the microwaves, for example its half-width, if the portioned material and/or the comparative portioned material and/or the gas phase in the measurement chamber show a not insignificantly low water content. In this case it is possible to obtain information on the water content from the imaginary part of the dielectric function which can be determined from the variation in attenuation of the spectral resonance signal.

The invention will be described in more detail below with reference to the attached drawings of particularly advantageous embodiments, without limiting the general concept of the invention underlying these embodiments, which also show further advantages and possible applications. They show:

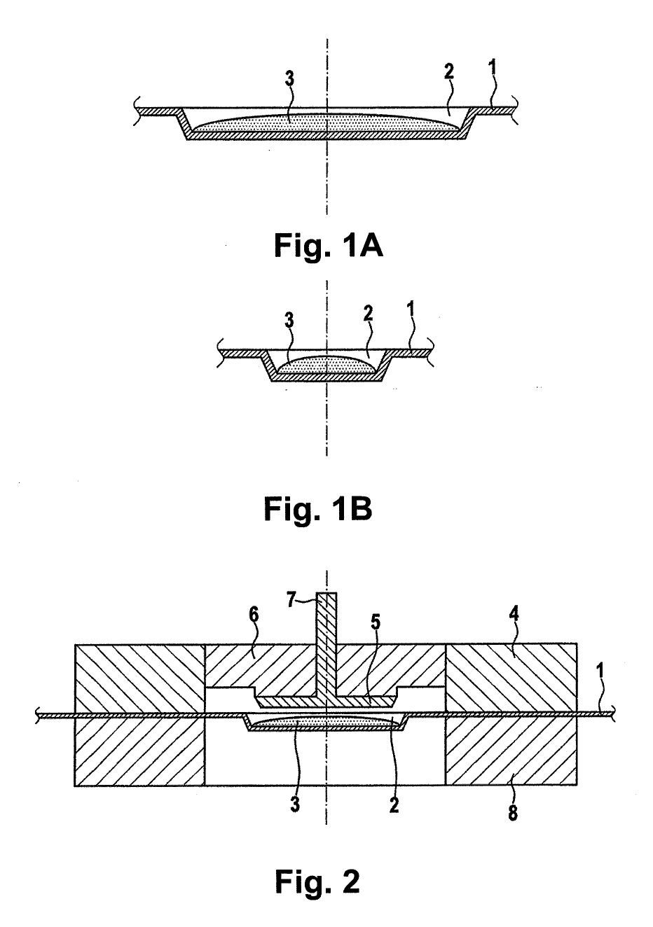

FIG. 1 a longitudinal section of a capsule end package (left: along the horizontal major axis of the end package; right: along the horizontal minor axis of the end package),

FIG. 2 a longitudinal section along the horizontal major axis of a first embodiment of the dielectricity measurement device according to the invention together with a capsule end package in a measurement arrangement,

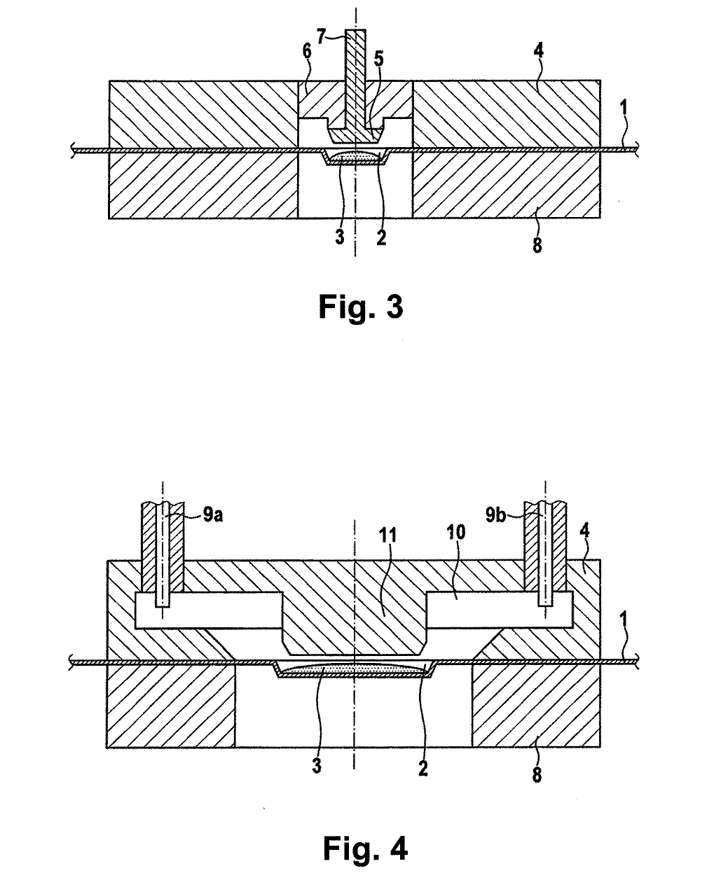

FIG. 3 a longitudinal section along the horizontal minor axis of the first embodiment of the dielectricity measurement device according to the invention shown in FIG. 2, together with the capsule end package in a measurement arrangement,

FIG. 4 a longitudinal section along the horizontal major axis of a second embodiment of the dielectricity measurement device according to the invention together with a capsule end package in a measurement arrangement,

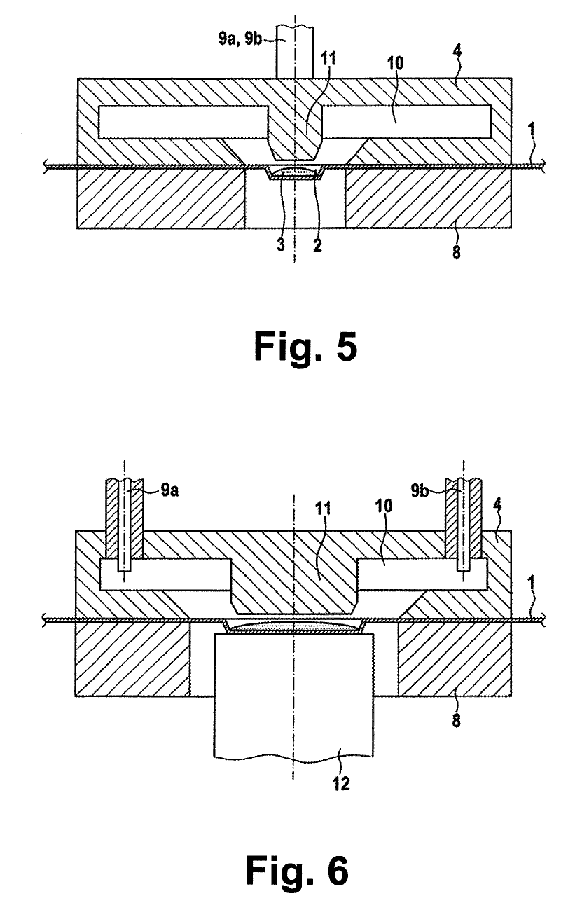

FIG. 5 a longitudinal section along the horizontal minor axis of the second embodiment of the dielectricity measurement device according to the invention shown in FIG. 4, together with the capsule end package in a measurement arrangement,

FIG. 6 a longitudinal section along the horizontal major axis of a modification of the second embodiment of the dielectricity measurement device according to the invention together with a capsule end package in a measurement arrangement,

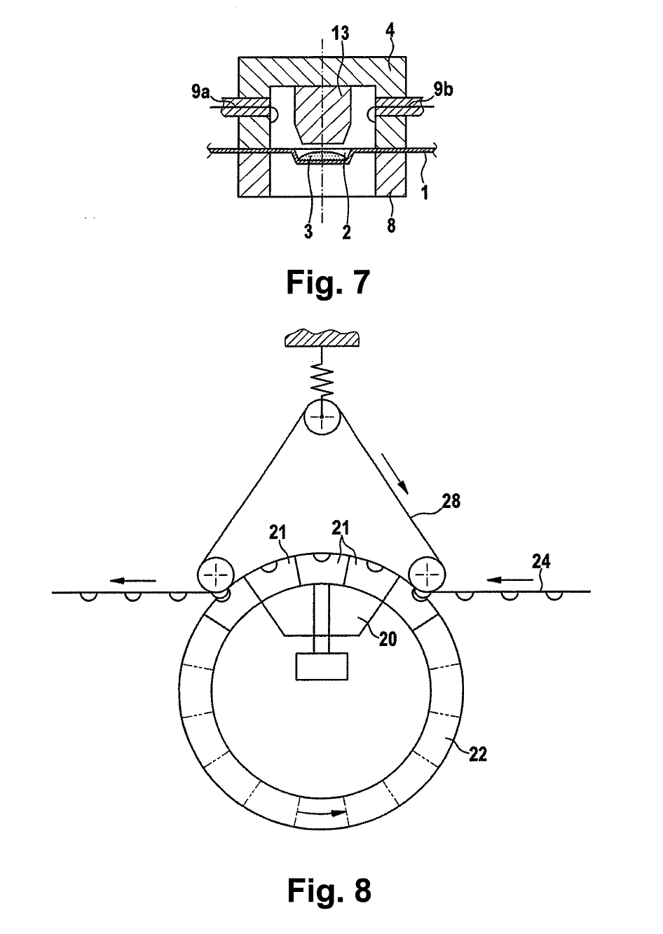

FIG. 7 a longitudinal section along the horizontal major axis of a third embodiment of the dielectricity measurement device according to the invention together with the capsule end package in a measurement arrangement,

FIG. 8 a schematic view of a fourth embodiment of the dielectricity measurement device according to the invention together with a plurality of capsule end packages in a measurement arrangement,

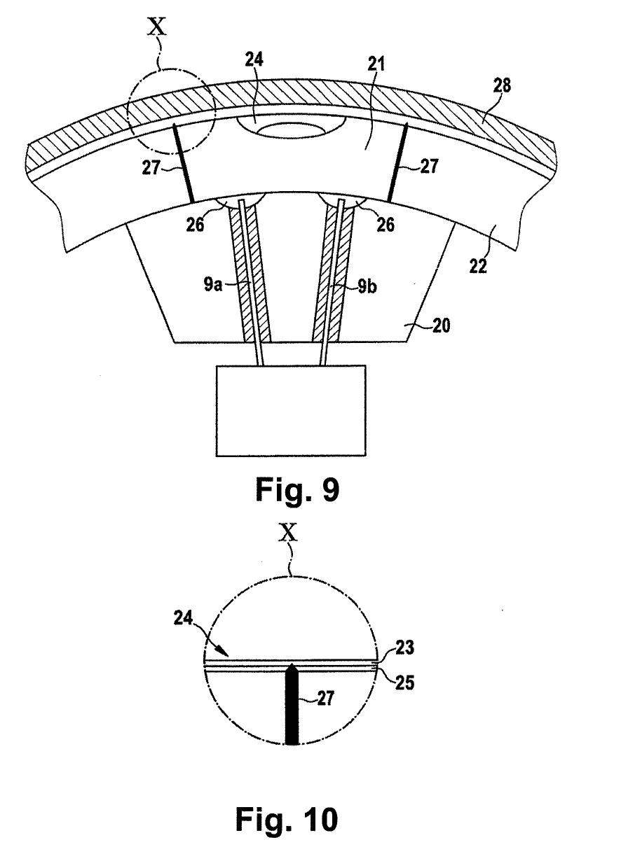

FIG. 9 an enlarged view of the measurement arrangement of the fourth embodiment of the dielectricity measurement device according to the invention shown in FIG. 8,

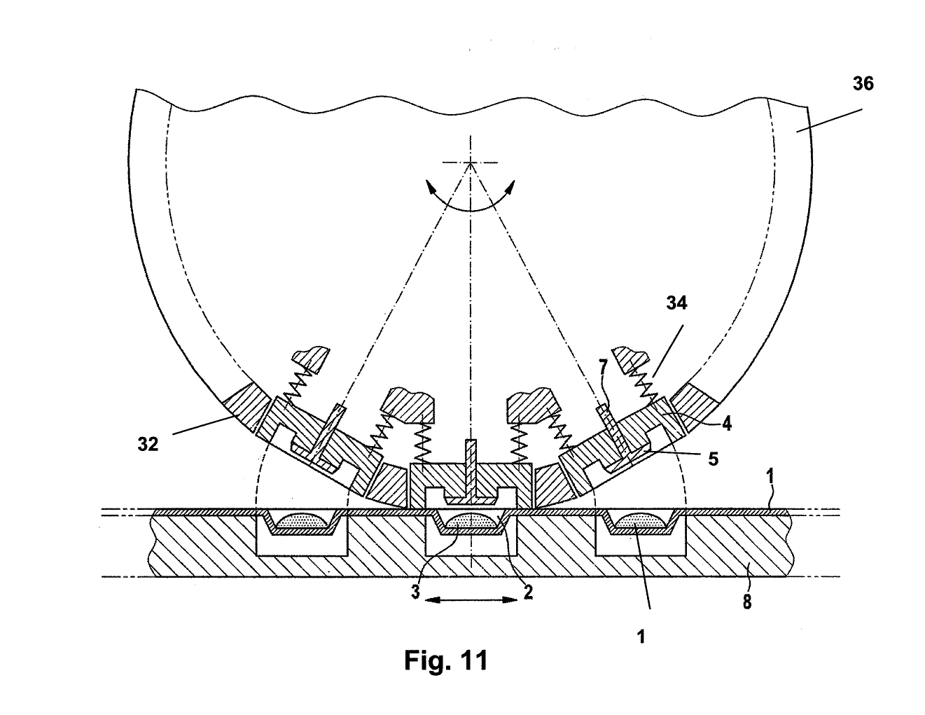

FIG. 10 an enlarged view of electrical contacting of the fourth embodiment of the dielectricity measurement device according to the invention shown in FIG. 9,

FIG. 11 a schematic view of an embodiment of the series measurement device according to the invention together with a plurality of capsule end packages,

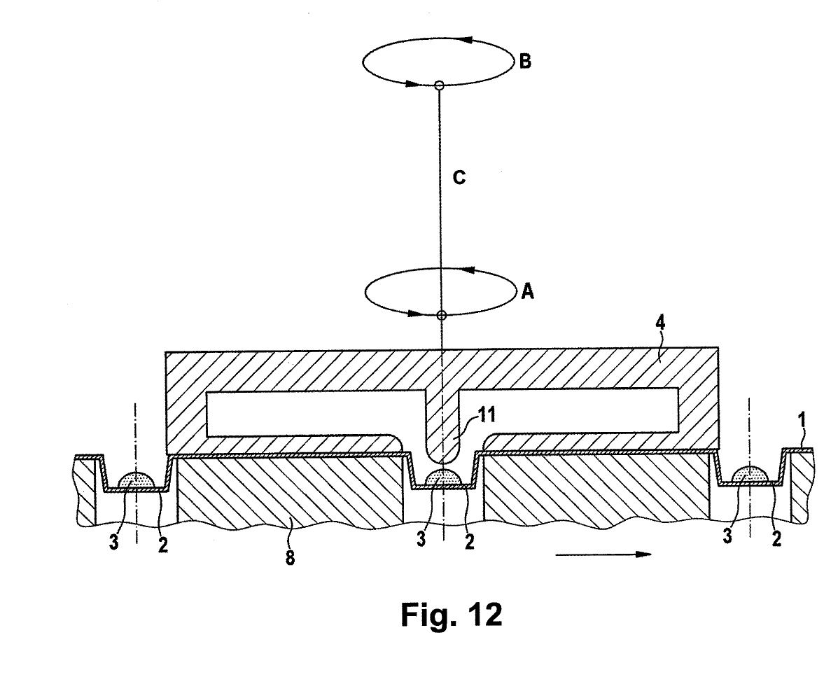

FIG. 12 a schematic view of a further embodiment of a series measurement device together with a plurality of capsule end packages,

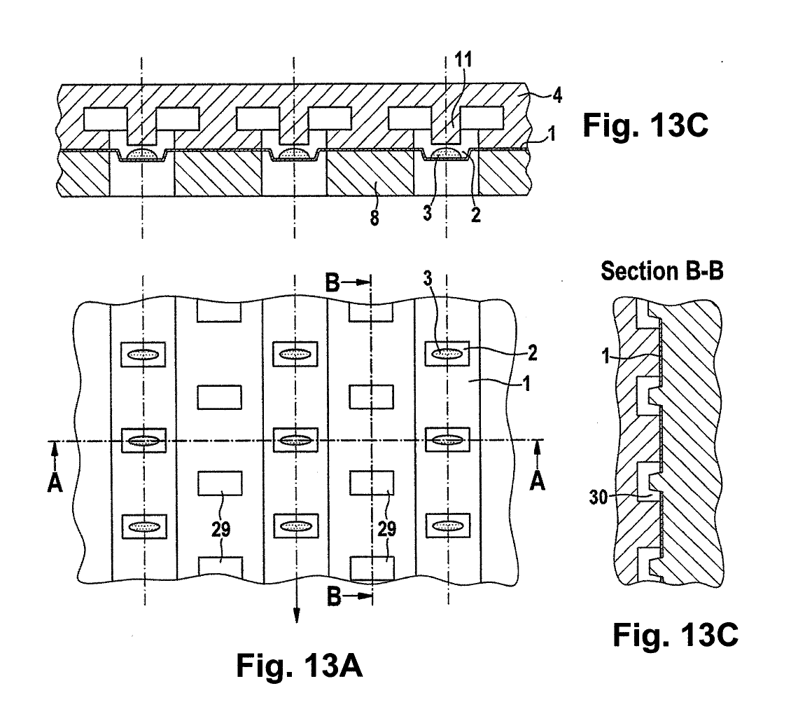

FIG. 13 a schematic view of a particular development of the embodiment of the series measurement device shown in FIG. 12 (bottom left: top view; top: section along the line of A-A; bottom right: section along the line B-B),

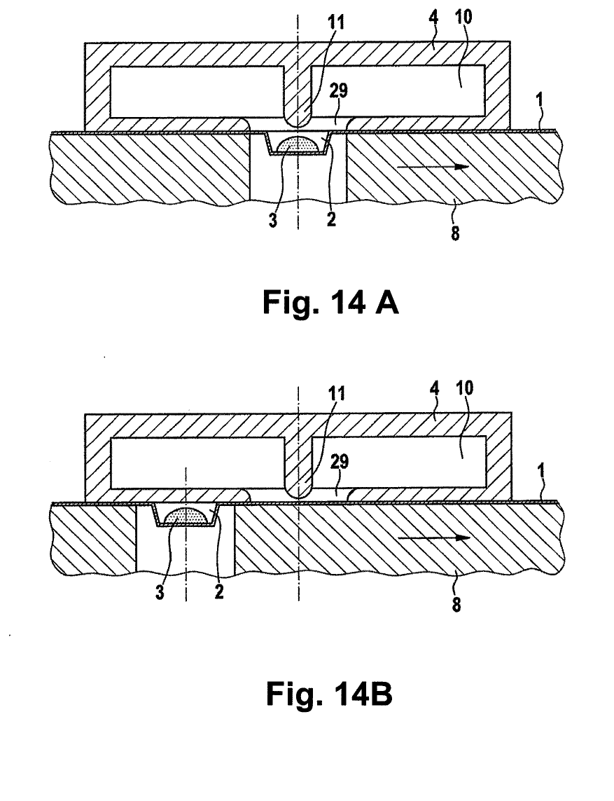

FIG. 14 a schematic view of a further embodiment of a series measurement device, and

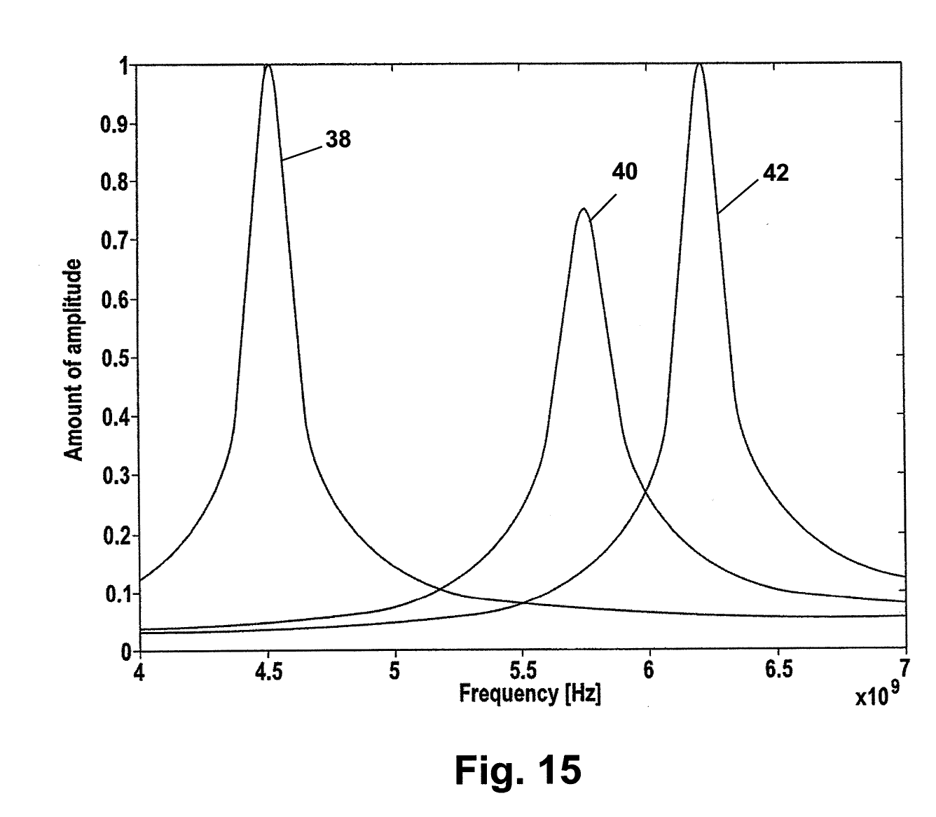

FIG. 15 schematic signal paths which were recorded at different operating points with the embodiment of the series measurement device shown in FIG. 14.

In FIG. 1 (left and right) are shown sections along two different axes of a capsule end package. The capsule end package comprises a receiving portion 1 which is designed as a shaped aluminium portion with a depression or trough 2 for receiving the portioned material 3. The portioned material 3 is here in the form of a powder. Naturally profiled parts made of different materials as well as those with a different shape can be used as the receiving portion. The capsule end package shown in FIG. 1 is not yet finally glued to a closure portion made of a plastic film or metal foil.

In FIGS. 2 and 3 are shown sections along two different axes of a first embodiment of the dielectricity measurement device of the invention. The dielectricity measurement device is here designed as part of an electrical measurement capacitor for determining dielectric properties of portioned material 3 of a capsule end package. The dielectric properties of the powdered portioned material 3 which is located in the electrical-field of the measurement chamber are used to determine the quantity of portioned material. The receiving portion 1 of the capsule end package is here clamped between the two snug-fitting counter surfaces 4 and 8 and therefore fixed. As a result the portioned material 3 as well as the receiving portion 1 of the capsule end package is precisely defined with respect to spatial position.

At least the upper counter surface 4 is here designed to be electrically conductive, so that there is an electrical connection between the metal receiving portion 1 of the capsule end package and the dielectricity measurement device. In the present case, therefore, trough 2 and the inner region of the receiving portion 1 arranged round the trough 2 serve as an electrically conductive package wall of the capsule end package. In addition, likewise the lower counter surface 8 can be designed to be metallically conductive.

Centrally, the upper counter surface 4 has an opening in which is embedded an auxiliary element 6 as a spacer made of an insulating material of low conductivity and a very low loss factor, preferably a ceramic material. Here, however, care is to be taken that no further stray capacitances form between the first measurement electrode 5 and the electrically conductive counter surface 4. By means of the auxiliary element 6, precise positioning of the plunger-like first measurement electrode 5 which in this embodiment forms the first measurement means from the electrically conductive wall portion is possible. The potential of the first measurement electrode of the capacitive sensor assembly extends via the connecting wire 7 out of the measurement chamber.

If an electrical potential which differs from the potential of the first measurement electrode 5 is applied to connecting wire 7, as a result of the high conductivity of the metal receiving portion 1 and as a result of the short distance between the first measurement electrode 5 and the receiving portion 1 as the second measurement electrode, an electrical field forms between the two measurement electrodes within the measurement chamber.

Between the electrically conductive counter surface 4 and the connecting wire 7, therefore, there arises a capacitance which is firstly dependent on the specific measurement arrangement, but also strongly defined by the electrical properties and the quantity of portioned material 3 which is located in the trough 2 in the package wall of the capsule end package.

The generally complex capacitance can be determined by conventional measurement methods. Thus for example in the present case the dielectricity measurement device is operated in an external oscillating circuit of which the resonant frequency and resonant attenuation are influenced by the portioned material 3.

For measurement, the upper counter surface 4 is lifted off the lower counter surface 8. In this arrangement the metal receiving portion 1 of the capsule end package is laid in the recess in the lower counter surface 8 and, if need be, aligned by means of possible guide elements. Now the upper counter surface 4 is lowered back down onto the lower counter surface 8, the edge regions of the metal receiving portion 1 being fixed in clamping relationship between the upper counter surface 4 and the lower counter surface 8. By fixing in clamping relationship, galvanic contact is made between the upper counter surface 4 and the metal receiving portion 1. In general the result here is an arrangement in which the lower section of the measurement electrode 5 is arranged at a distance from the upper section of the metal receiving portion 1 and therefore also from the portioned material 3.

In this arrangement, actual measurement of the dielectric properties is carried out. From the measurement results the values for the dielectric properties are calculated by taking into consideration the dielectric properties of the unfilled measurement arrangement, that is, without portioned material, either in the form of a previous calibration or as measurement results of a reference measurement on the respective unfilled metal receiving portion 1 in the measurement arrangement.

After measurement, the upper counter surface 4 is again lifted off the lower counter surface 8, and the filled metal receiving portion 1 is taken away from the lower counter surface 8. The measurement arrangement is now available for a further measurement.

The mass of the portioned material can be determined from the dielectric properties of the portioned material obtained in this way, by setting the value for the corresponding properties in relation to a value of the same dielectric properties which was previously determined on a sample of known mass of which the composition is substantially identical with that of the portioned material to be tested.

In FIGS. 4 and 5 are shown sections along two different axes of a second embodiment of the dielectricity measurement device of the invention. The dielectricity measurement device is here designed as part of a microwave resonator for determining dielectric properties of portioned material 3 of a capsule end package. The dielectric properties of the powdered portion material 3 which is in the measurement chamber are here too used to determine the mass of the portioned material 3. The receiving portion 1 of the capsule end package is here clamped as an electrically conductive package wall between the two snug-fitting counter surfaces 4 and 8, and so fixed. As a result the portioned material 3 and the receiving portion 1 of the capsule end package are precisely defined with respect to spatial position.

The upper counter surface 4 is designed as a resonator body and therefore electrically conductive, so that there is an electrical connection between the metal receiving portion 1 of the capsule end package and the wall portions of the dielectricity measurement device. In the present case, therefore, likewise trough 2 and the inner region of the receiving portion 1 arranged round trough 2 serve as the electrically conductive package wall of the capsule end package.

The properties of a resonator body are basically predetermined by the dimensions of the measurement chamber 10 and therefore substantially by the geometry of the upper counter surface 4. The upper counter surface 4 in the present case has, in place of the first measurement means, a lug-shaped protrusion or arch of the interior 11, of which the cross-section is adapted to the cross-section of trough 2 of the capsule end package, almost engages in the latter and so nearly touches the portioned material 3.

Basically, electromagnetic waves with any suitable modes of oscillation (modes of propagation) can be coupled into the resonator, and therefore for example those with a mode of oscillation with a transverse magnetic field (TM oscillation mode) or those with a mode of oscillation with a transverse electrical field (TE oscillation mode). It is, however, particularly advantageous if electromagnetic radiation with a TM01 mode of oscillation is coupled to the resonator, and in this way the local field strength of the alternating electrical field in the region of the portioned material 3 is particularly high. This can be achieved by using a suitably mounted input probe 7 as the first coupling element which excites the corresponding mode of oscillation. Within the measurement chamber of the dielectricity measurement device, diametrically opposite the input probe 7, is arranged a measurement probe 8 as the second coupling element for output of the electromagnetic radiation, by means of which the measurement signal is transmitted.

As a result of using the TM01 mode of oscillation, essentially the dielectric properties of the portioned material 3 and its quantity influence the spectral position of the peak of the resonance signal (the resonant frequency) as well as the widening of the spectral resonance curve (the resonant attenuation).

The process of a measurement which is performed using a microwave resonator is essentially the process described above for the use of a measurement capacitor. On lowering the upper counter surface 4, however, the result here is an arrangement in which the lower section of the lug-like protuberance of the interior 11 is arranged at a distance from the upper section of the metal receiving portion 1 and so also from the portioned material 3.

In FIG. 6 is shown a section through a modification of the second embodiment of the dielectricity measurement device of the invention. In addition to the second embodiment of the dielectricity measurement device of the invention shown in FIGS. 3 and 4, this modification has a support element 12 which serves to support the receiving portion 1 of the capsule end package on the underside and so prevents variation of the geometry of the resonator chamber in time, for example as a result of vibrations which might be transmitted to the otherwise freely suspended trough region of the receiving portion of the capsule end package and so might falsify a measurement. Naturally, a support element of this kind can also be provided in the case of a capacitive dielectricity measurement device.

In FIG. 7 is shown a section through a third embodiment of the dielectricity measurement device of the invention. The dielectricity measurement device is here designed as part of a microwave resonator for determining dielectric properties of portioned material 3 of a capsule end package. Unlike the second embodiment, the measurement chamber which is designed as a resonator chamber contains a dielectric resonator packing which is designed as a dielectric resonator. Here too, the cavity resonator is formed by the electrically conductive wall portions of the upper counter surface 4 in cooperation with the electrically conductive package wall of the capsule end package, the first measurement means in the present case being concealed by the resonator packing 13. The receiving portion 1 of the capsule end package is here too clamped as an electrically conductive package wall between the two snug-fitting counter surfaces 4 and 8 and therefore fixed. Hence the spatial position of the portioned material 3 as well as that of the receiving portion 1 of the capsule end package is fixed exactly.

As a result of the high dielectric function of the material of a dielectric resonator packing, such a resonator packing makes it possible within a fixed frequency range for microwaves to use a microwave resonator with significantly smaller dimensions than in an arrangement without a dielectric resonator packing. As is known, the spectral position of the peak of a microwave resonance signal as well as the attenuation of the resonance curve (for example its half-width) when using microwave radiation of oscillation mode TM01 for a microwave resonator with a dielectric resonator packing is also influenced by axially mounted dielectrics. In the present case this oscillation mode is obtained via a first coupling element 9a which is designed as a conductor loop and which generates a magnetic field in the circumferential direction of the cylindrical measurement chamber. With this arrangement too, diametrically opposite is provided a second coupling element 9b similarly designed with a conductor loop for output of the microwave radiation.

FIGS. 8, 9 and 10 show schematic views of a fourth embodiment of the dielectricity measurement device according to the invention which is particularly suitable for measuring portioned material in a microwave resonator with continuously conveyed package walls of capsule end packages.

For the measurement of dielectric properties of portioned material in a microwave resonator, a closed resonator housing is required. This closed cavity resonator is formed in the fourth embodiment by three individual elements: a stationary coupling shoe 20, wall frames 21 in a rotatable cassette element 22, and a metal closure portion of a capsule end package 24.

The stationary coupling shoe 20 forms the bottom section of the resonator chamber. The coupling shoe 20 has an articulate upper side in which are formed hollows 26. In these depressions 26 are embedded short capacitive coupling aerials 9a, 9b as coupling elements which are insulated from the electrically conductive coupling shoe 20.

The wall frames 21 on the rotatable cassette element 22, which is designed as a star wheel, here form the side walls of the resonator chamber. Between the two spaced-apart circular rings are arranged webs by which almost rectangular chambers are divided, which are in each case bounded by the wall frame 21. The coupling shoe 20 in this case is applied to the feeder wheel 22 on the inside of the circular rings.

The top section of the resonator chamber opposite the bottom section is formed by a metal cover foil 23 of the closed capsule end package 24. The capsule end packages 24 from the product stream, which in the present case are designed as blister strips, are pressed against the circular rings and webs of the feeder wheel 22 with the receiving portion side by means of a pretensioned contact-pressure belt element 28. As the receiving portion is frequently composed of a non-conductive moulded polymer portion 25, the feeder wheel 22 is provided at its outer circumference with metal needle probes 27 which pass through the plastic 25 and ensure electrically conductive contact between the wall frames 21 and the electrically conductive closure portion 23 of the capsule end package 24 as its package wall (FIG. 10). As a result, the capsule end packages 24 should each have only a relatively thin plastic film 25 which is welded to the metal foil 23 at its outer circumference and therefore relatively close to the wall frame 21 of the cell, so that the interior of the capsule end packages 24 remains closed when the plastic films 25 are pierced with the needle probes 27.

The assembly is operated in such a way that one capsule end package 24 each is received at the outer opening of a cell of the feeder wheel 22 and transported. With continuous transport, therefore, the capsule end package 24 is initially located stationarily at the resonator cell which is passing over the coupling shoe 20. As soon as both coupling aerials 9a, 9b are located within the resonator cell, the microwave generator is activated and sends a signal to the input aerial for input into the measurement chamber. Due to the relative movement of the aerials 9a, 9b and the resonator cell in relation to each other which results from the movement of the feeder wheel 22, the field in the resonator is excited to different degrees. Therefore the output signal has a periodic curved path which reproduces the transit time of the resonance cell via the coupling aerials 9a, 9b. This path is scanned at the scanning rate available in conventional systems, for example at a scanning rate of approximately 10 kHz.

In an evaluation unit, the signal is determined with optimum coupling and from this is calculated the filling weight of the capsule end package 24. Optionally, it may be an advantage here if the signal path is detected and analysed for the whole travel of the coupling points through the resonator.

The capsule end packages are in this case advantageously transported through the measurement arrangement in such a way that the portioned material therein is as far away as possible from the metal foils. This is the case, for example, if the receiving region of the receiving portion of the capsule end package is directed downwards from overhead into the resonator chamber, that is, in a suspended arrangement such as is possible for capsule end packages that are already closed.

At a scanning rate of the microwave system of 10 kHz, in this way up to 100 capsule end packages a second could be measured if, on passage of a resonator cell, 100 measurements are performed each time.

One embodiment of the series measurement device according to the invention is shown in FIG. 11. The sectional view shows in the upper part the first combination element designed as a roller frame. At its circumference the cylindrical roller frame has dielectricity measurement devices (in FIG. 11 for the sake of clarity only three of these dielectricity measurement devices are shown). The dielectricity measurement devices comprise the upper counter surface 4 and the measurement electrode 7.

The dielectricity measurement devices fit in the roller frame and are separated from each other by distance pieces. Each dielectricity measurement device is in this case radially springmounted by spiral springs which provide a high contact pressure directed away from the cylinder axis and, as a result of the individual movable arrangement of each dielectricity measurement device, also ensure mechanical contact with different package walls. On rotation of the roller frame about its centre axis, the dielectricity measurement devices are pressed against the upper sides of the package walls of the capsule end packages which are mounted underneath, and so form in each case a measurement arrangement.

The electrically conductive package walls of the capsule end packages are here designed as a continuous blister strip on which a plurality of not yet encapsulated (and therefore not connected to the closure portion) receiving portions 1 are arranged serially one behind the other. The package walls in the present case are made of a plastic laminate which also has an aluminium layer. The blister strip can be designed as an endless strip which is delivered continuously to a series measurement device, or as a single blister sheet, for example in the form of a so-called “print” of 100 trough regions in an arrangement of 10 rows and 10 columns, which is delivered to a series measurement device discontinuously in batch mode. The receiving portions 1 are arranged horizontally for measurement on the first combination element which is designed as the lower counter surface 8 in the form of a pallet frame. The pallet frame 8 contains a matrix-like arrangement of individual depressions which are adapted to receive the receiving portions 1. As a result of the matrix-like arrangement of depressions in rows and columns, in each case several receiving portions 1 can be arranged parallel to each other (in a row) and in addition a plurality of receiving portions 1 are arranged one behind the other (in a column). The pallet frame 8 is linearly movable and can be moved by a drive element (not shown).

The unfilled receiving portions 1 introduced into the depressions of the pallet frame 8 are transported on the pallet frame 8 to a filling device. In the filling device, filling of the receiving portions 1 takes place in volumetrically controlled discharge of a powdered pharmaceutical as the portioned material 3.

For measurement, the region of the pallet frame 8 which contains the receiving portions 1 to be measured is moved in a linear movement past and underneath the roller frame. The cylindrical roller frame is mounted rotatably in the cylinder centre axis and is rotated by means of a drive element in such a way that the path speed of its shell is exactly the same as the linear speed of the pallet frame 8. As a result of this movement in the same direction and at the same speed, in each case a dielectricity measurement device comes into contact with a receiving portion 1 at the lowermost point of the roller frame, each dielectricity measurement device being pressed by spiral springs against the corresponding receiving portion 1, forming one measurement arrangement each as a result.

Since in the present case the roller frame has several dielectricity measurement devices parallel and adjacent to each other at its circumferential surface, several measurement arrangements are formed parallel and adjacent to each other simultaneously. If, for example, a roller frame has ten dielectricity measurement devices one behind the other and ten dielectricity measurement devices in each case adjacent to each other along its circumference, 100 measurement arrangements can be formed and individual measurements performed to every rotation of the roller frame.

The measurement electronics of the dielectricity measurement device are designed to perform a measurement at exactly the moment when the measurement arrangement is formed at the lowermost point of the roller frame. Due to the rotary movement of the roller frame, individual measurements are performed in rows on a plurality of receiving portions 1. After these measurements the receiving portion 1 is moved back out of the measurement gap as a result of the continuous linear movement of the pallet frame 8. With the rotary movement of the roller frame coordinated with this linear movement, the time required for measurement can be further reduced.

In addition, before filling the receiving portions 1 an empty measurement can be performed, in which the pallet frame 8 with the unfilled receiving portions 1 is transported under the roller frame and a measurement is performed, as a result of which reference values are obtained for the actual measurements with the receiving portions 1.

To further improve contact between the package walls on the one hand and the dielectricity measurement devices on the other hand, naturally the second combination element can also be designed as a roller frame in the shells of which the depressions are arranged for receiving the receiving portions 1.

Although in the present case only one measurement arrangement with measurement capacitors is described for the series measurement device according to the invention, the series measurement device can of course also comprise measurement arrangements with microwave resonators.

As an alternative to the design of the first combination element as a roller frame, this can also be designed differently, for example as a matrix frame. The latter can be for example a one-dimensional (and therefore linear) matrix frame which has several dielectricity measurement devices arranged parallel and adjacent to each other, for example in the form of a measurement row. A measurement row of this kind can have for example ten dielectricity measurement devices parallel and adjacent to each other. In this way likewise a measurement of dielectric properties performed row by row transversely to the direction of movement of the pallet frame 8 is possible, for example by lowering the matrix frame onto the linearly forwardly moved pallet frame with the receiving portions 1, performing the parallel measurements, and then raising the matrix frame again.

To avoid frequent lowering and lifting of the matrix frame, the matrix frame can also be a two-dimensional (and therefore planar) matrix frame, for example a measurement plate. A measurement plate of this kind can have for example ten dielectricity measurement devices parallel and adjacent to each other and in each case ten dielectricity measurement devices one behind the other, that is, a total of 100 dielectricity measurement devices in a planar arrangement, so that 100 measurements can be performed simultaneously.

In FIG. 12 a further embodiment of a series measurement device is shown schematically. The capsule end packages are here designed as an endless blister belt of which the receiving portion 1 has a plurality of depressions 2 arranged one after the other for receiving the portioned material 3, which are in each case spaced apart by flat sections. The electrically conductive wall portion designed as the receiving portion 1 is here made by way of example from a laminate of aluminium foil and polymer layers, which is not yet encapsulated with a covering film for measurement, but, filled with the portioned material 3, moved past the dielectricity measurement device on a lower counter surface 8 (see arrow direction). Likewise it is also possible to use other capsule end packages, for example those in which the receiving portions are already encapsulated with a plastic covering film during measurement. Corresponding to the distances between the depressions 2 of the receiving portion 1, the lower counter surface 8 in the present case has recesses for receiving the depressions 2.

The dielectricity measurement device is designed as a cavity resonator with an upper counter surface 4 (coupling elements are not shown in FIG. 12 for the sake of clarity). The cavity resonator has a lug-like protuberance 11 which in the present case at least partially engages in the filling volume of the depression 2 of the receiving portion 1. The outer edge regions of the upper counter surface 4 on the lower side lie flat against the upper side of the flat sections of the receiving portion 1. The supporting regions on the upper side of the lower counter surface 8 lie flat against the lower side of the flat sections of the receiving portion 1. As a result, overall good mechanical contact is provided between the receiving portion 1 and the cavity resonator.

At the moment shown in FIG. 12 from the measurement cycle the dielectricity measurement device is lowered onto the receiving portion 1 and the central depression 2, and so forms with them at the central measurement point a measurement arrangement. The direction of movement of the dielectricity measurement device is indicated by the direction ellipses A, B shown schematically at the centre axis C of the dielectricity measurement device: if the lower counter surface 8 with the receiving portion 1 is now moved in the arrow direction, the upper counter surface 4 is first moved along the receiving portion 1 in the arrow direction at approximately the same speed. As a result of the elliptical path A, B of the upper counter surface 4, the latter is then lifted off the upper side of the receiving portion 1 and moved away from the latter as far as the rear turning point of the movement, the right major apex of the ellipse A, B. In the top half of the elliptical path of movement A, B, the upper counter surface 4 is guided in the direction opposite the direction of movement of the lower counter surface 8 as far as the front turning point, the left major apex of the ellipse A, B, and so can be lowered back down onto the blister belt in order to form a further measurement arrangement with the next depression. The actual recording of measured values here takes place by a suitable known measurement method in the lower minor apex of the elliptical movement A, B.

By adjustment of the elliptical movement to the sequence of successive depressions, precise positioning in all three spatial directions is also possible in continuous mode in rapid succession. This adjustment includes both allowing for the dimensions of the individual components (that is, for example the dimensions of the upper counter surface 4 and the distance between two successive depressions 2) as well as their movement (for example circumference and path speed/angular velocity of the elliptical path A, B and speed of advance of the lower counter surface 8). In the present case the distance between two successive depressions 2 in the direction of movement of the receiving portion 1 is selected so that the latter corresponds to twice the length of the major axis of the ellipse A, B.

FIG. 13 shows an improvement to this arrangement. At the bottom left a top view of the plane of the package is shown schematically. The capsule end package is here shown as a parallel arrangement of blister belts connected to each other, of which the receiving portion 1 is made from a metal foil/plastic laminate and has rectangular depressions 2 which contain the portioned material 3. The upper counter surface 4 is lowered from above onto this receiving portion 1 in an elliptical path. In the present case the capsule end packages are not yet encapsulated with a covering film (see sectional view of the section along the line A-A in the upper part of FIG. 13). Naturally, the capsule end package can also be tested already encapsulated, for example with a covering film made of a polymeric plastic.

Between the strips with the depressions 2, the receiving portion 1 in addition has strips with recesses 29 which are adapted to receive receiving elements 30.

The recesses 29 here are rectangular punched holes of which the position and arrangement in relation to the depressions 2 are fixed exactly. The receiving elements 30 are arranged as frustopyramidal teeth on the lower side of the upper counter surface 4, of which the position and arrangement in relation to the dimensions of the resonator are likewise fixed exactly. The position and dimensions of the recesses 29 are here adjusted to the dimensions of the receiving elements 30 in such a way that the receiving elements 30 engage in the recesses 29 when the upper counter surface 4 is lowered onto the receiving portion 1. As a result, the receiving portion 1 is oriented relative to the upper counter surface 4 and the position of the receiving portion 1 is fixed exactly in the measurement arrangement (see sectional view of the section along line B-B in the bottom right part of FIG. 13). This effect can also be obtained by using other receiving elements.

FIG. 14 shows a further embodiment of a series measurement device in which the capsule end packages are moved past a stationary dielectricity measurement device which is designed as a cavity resonator. The capsule end package in the example shown here is a blister pack which has a receiving portion 1 with a depression 2 for receiving the portioned material 3. The receiving portion 1 is designed as a not yet encapsulated metal foil/plastic laminate, but other embodiments of receiving portions can be used too, for example those with plastic covering films.

The receiving portion 1 is received by a lower counter surface 8 in such a way that the depression 2 of the receiving portion 1 is arranged in a recess of the lower counter surface 8. The lower counter surface 8 is moved past an opening 31 which is located in the upper counter surface 4 at the lower end of the measurement chamber 10, at the centre of which is arranged a lug-like protuberance 11 of the upper counter surface 4. The lower side of the upper counter surface 4 in this case is located against the flat upper side of the receiving portion 1, and the lower side of the receiving portion 1 abuts against the upper side of the lower counter surface 8.

Upon movement of the receiving portion 1 past the dielectricity measurement device, the lower counter surface 8 with the receiving portion 1 is moved along the lower side of the fixed upper counter surface 4, with close mechanical contact between the receiving portion 1 and the cavity resonator. Therefore the lower side of the upper counter surface 4 should be flat to allow low-resistance, low-damage movement of the receiving portion 1.

In the upper part of FIG. 14 is shown the moment when the receiving portion 1 is arranged immediately below the opening 31 of the upper counter surface 4 and therefore the wall portion of the capsule end package and the dielectricity measurement device are located in a measurement arrangement. This moment corresponds to the moment when an optimum measurement signal can be obtained, as the depression 2 with the portioned material 3 is located completely under the lug-like protuberance 11. By contrast, FIG. 14 shows a moment when a flat section of the receiving portion 1 is located under the opening 31 of the upper counter surface 4, so that the cavity resonator is completely closed.

If now the measurement signal is recorded continuously while the depression 2 is moved past the opening 31, then it is possible to obtain from the trend of the signal in time the measurement signal which shows a maximum deviation. By using the signal of maximum deviation, it is not necessary to position the receiving portion 1 exactly in relation to the dielectricity measurement device in the three spatial directions for each measurement. This is because, during the movement of the receiving portion 1 past the opening 31, at the same time there is an optimum arrangement of the depression 2 relative to the upper counter surface 4, so that exact positioning is not necessary. At the same time, with this method a high precision of measurement is also guaranteed for measurements in quick succession. This is particularly important when the depression is irregularly shaped.

Three examples of signals for a cavity resonator assembly are shown in FIG. 15. The left signal curve here shows the signal path for a measurement in which a flat section of the receiving portion 1 is arranged directly beneath the opening 31 of the upper counter surface 4. In this case the resonant frequency is particularly low due to the short distance from the lug-like protuberance 11 to the electrically conductive package wall, and the attenuation of the signal is only low. In the case of a series measurement, this measured value serves in each case as the reference measured value by which the maximum deviation is determined.

If the lower counter surface 8 is moved with the receiving portion 1, the distance between the lug-like protuberance 11 and the electrically conductive package wall becomes greater and the resonant frequency increases until finally the maximum distance is reached when the depression 2 in the receiving portion 1 filled with the portioned material 3 is located directly beneath the opening. At the same time the signal amplitude is lowered due to the dielectric losses and attenuation occurs. The middle curve in FIG. 15 shows this case.

The right curve in FIG. 15 shows the trend of the curve for depression 2 which is not filled with portioned material 3 and which is located directly under the opening 31 of the cavity resonator. Due to the long distance between the package wall and the lug-like protuberance 11 on the one hand and due to the empty sample space on the other hand, the resonant frequency in this case is particularly high without attenuation being observed here. This signal trend is shown only for the sake of clarity, as such a measurement curve is usually recorded only for calibration of the system and should not occur within the framework of a conventional series measurement.

At the beginning of a series measurement, first a flat section of the receiving portion 1 is arranged in front of the opening 31 of the dielectricity measurement device, and so the measurement signal shows a low resonant frequency. If the depression 2 is moved continuously past the opening 31 of the dielectricity measurement device, the resonant frequency likewise varies continuously towards greater resonant frequencies, beginning with entry of the opening of the depression 2 into the region beneath the opening 31 of the dielectricity measurement device. The highest resonant frequency occurs when the whole of the opening of the depression 2 is located beneath the opening 31 of the dielectricity measurement device. Insofar as this corresponds to an optimum measurement arrangement, further measures for exact positioning of the receiving portion 1 relative to the dielectricity measurement device are therefore not necessary.

In these embodiments too, the variation in the frequency and attenuation which occurs when, instead of an empty depression 2, a depression filled with portioned material 3 is brought under the opening 31 into a measurement arrangement with the dielectricity measurement device, serves as a measure of dielectric properties of the quantity of portioned material and hence of the quantity of substance.

For all embodiments, the circuit elements of the electronic detection means which are critical for the precision of measurement are preferably arranged in the immediate vicinity of the electrodes of the dielectricity measurement device. This ensures that the effect of the length of the signal wire on the signals to be measured is on the whole as small as possible. Also, in this way any effect due to variation in the signal wire conduction and the specific arrangement of signal wires is minimised.

1. A dielectricity measurement device for determining dielectric properties of portioned material of a capsule end package with the aid of an electrical field, wherein the capsule end package includes an electrically conductive package wall that includes a portioned-material region to receive the portioned material, the dielectricity measurement device comprising:
a first measurement device including an electrically conductive wall portion that defines in part a measurement chamber, and a receiving region adapted to temporarily receive and position at least one electrically conductive package wall of the capsule end package that forms a temporary measurement device into a measurement arrangement with the first measurement device.

2. The dielectricity measurement device of claim 1, wherein the first measurement device and the temporary measurement device are separated by a space defining a portioned-material chamber for the portion material to be tested.

3. The dielectricity measurement device of claim 1, wherein the first measurement device and the temporary measurement device have parallel, mutually opposed surfaces when in the measurement arrangement so that the field lines of the electrical field in the measurement chamber at the surfaces are perpendicular to the parallel, mutually opposed surfaces.

4. The dielectricity measurement device of claim 1, wherein the first measurement device and the temporary measurement device temporarily form an electrical measurement capacitor when in the measurement arrangement for determining dielectric properties of portioned material of a capsule end package.

5. The dielectricity measurement device of claim 4, wherein the first measurement device is a first measurement electrode, the temporary measurement device is a second measurement electrode, and the second measurement electrode is electrically insulated from the first measurement electrode.

6. The dielectricity measurement device of claim 1, wherein the first measurement device has a first coupling element for the input of microwave radiation into the measurement chamber and a second coupling element for the output of microwave radiation from the measurement chamber, the first measurement device is part of a microwave resonator for determining dielectric properties of the portioned material of a capsule end package, and the first measurement device is designed to temporarily form the microwave resonator together with the temporary measurement device when the temporary measurement device is in the measurement position.

7. The dielectricity measurement device of claim 6, wherein the first measurement device is a partial region of an inner wall of a cavity resonator, the temporary measurement device is a further partial region of the inner wall of the cavity resonator, the first measurement device and the temporary measurement devices are electrically connected to each other by further partial regions of the inner wall of the cavity resonator, and, together with the further partial regions of the inner wall, temporarily form the cavity resonator when the temporary measurement device is in the measurement position.

8. The dielectricity measurement device of claim 6, wherein the first measurement device has a form that is adapted to a form of the temporary measurement device such that the first measurement device is a short distance from the temporary measurement device and from the surface of the portioned material introduced into the capsule end package.

9. The dielectricity measurement device of claim 6, wherein the dielectricity measurement device has a dielectric resonator filling element with a high dielectric constant in the measurement chamber close to the first measurement device.

10. The dielectricity measurement device of claim 9, wherein an end section of the resonator filling element arranged closest to the temporary measurement device is a short distance from the temporary measurement device and from the surface of the portioned material introduced into the capsule end package.

11. The dielectricity measurement device according to claim 6, wherein the measurement chamber comprises, as a boundary, side wall portions electrically connected to the first measurement device in the measurement arrangement, the side wall portions comprising a peripherally closed wall frame with a first bottom opening and a second bottom opening, and the first measurement device and a first bottom opening of the side wall frame being movable relative to each other and temporarily form the measurement chamber by at least partially form-locking.

12. The dielectricity measurement device of claim 11, wherein the dielectricity measurement device further comprises a movable cassette element containing a plurality of side wall frames connected to each other and, wherein the first measurement device constitutes a part of a stationary electrically conductive shoe, the cassette element and the shoe temporarily form the measurement chamber from the first measurement device and each of the plurality of wall frames by movement of the cassette element past the portion of the shoe designed as the first measurement device successively.

13. The dielectricity measurement device of claim 12, wherein the first measurement device is formed from a cylinder arc-shaped side surface of the shoe, the cassette element is mounted rotatably and has two parallel circular rings spaced apart from each other by a plurality of radially mounted intermediate frame walls such that two adjacent intermediate frame walls and two parallel circular ring segments are connected electrically to form the wall frame, two adjacent wall frames each have a common intermediate frame wall, the shoe being arranged relative to the cassette element to electrically connect the two circular rings in the region of the first bottom openings of the wall frames, so that upon rotation of the cassette element the dielectricity measurement device is formed in each case temporarily, and the wall frames of the cassette element having second bottom openings to the outside, and the temporary measurement device and the second bottom openings move closer together and with the latter are brought temporarily into a measurement arrangement.

14. The dielectricity measurement device of claim 13, wherein the cylinder arc-shaped side surface of the shoe has depressions in which the first and second coupling elements are received and are electrically insulated from the shoe.

15. A series measurement device for successively determining dielectric properties of portioned material of a plurality of capsule end packages, wherein the series measurement device comprises a plurality of dielectricity measurement devices according to claim 1, wherein the first measurement devices of the plurality of dielectricity measurement devices are arranged on a first combination element which is adapted to receive a plurality of temporary measurement devices.

16. The series measurement device of claim 15, further comprising a second combination element to receive the plurality of temporary measurement devices, the first combination element and the second combination element being movable relative to each other.

17. The series measurement device of claim 15, wherein the first combination element is a matrix frame in which the first measurement devices of the plurality of first measurement devices are each arranged parallel and adjacent to each other.

18. The series measurement device according to claim 15, wherein the first combination element comprises a cylindrical roller frame in which the first measurement devices of the plurality of first measurement devices are each arranged adjacent to each other on the shell of a cylinder roller.

19. A dielectricity measurement system comprising a dielectricity measurement device according to claim 1 and at least one electrically conductive package wall of a capsule end package.

20. A method for determining dielectric properties of portioned material of a capsule end package, employing the dielectricity measurement device according to claim 1, comprising the steps of:
transferring the portioned material to the portioned-material region of the electrically conductive package wall of the capsule end package,
subsequently introducing the package wall of the capsule end package with the portioned material into the dielectricity measurement device,
electrically connecting at least one electrically conductive portion of the package wall of the capsule end package to the dielectricity measurement device, wherein the dielectricity measurement device and the package wall of the capsule end package are temporarily brought into the measurement arrangement,
measuring dielectric properties of the measurement chamber of the dielectricity measurement device and of the package wall of the capsule end package with portioned material,
calculating dielectric properties of the portioned material from the result of measuring dielectric properties of the measurement chamber of the dielectricity measurement device and of the package wall of the capsule end package with portioned material.
after measuring dielectric properties of the measurement chamber of the dielectricity measurement device and of the package wall of the capsule end package with portioned material (3), taking the package wall of the capsule end package with the portioned material from the dielectricity measurement device.

21. The method of claim 20, wherein before transfer of the portioned material to the portioned-material region of the package wall of the capsule end package, the method further comprises measuring dielectric properties of the measurement chamber of the dielectricity measurement device and of the package wall of the capsule end package without portioned material and wherein the calculating step includes calculating based on the result of measuring the dielectric properties of the measurement chamber of the dielectricity measurement device and of the package wall of the capsule end package with portioned material and the result of measuring the dielectric properties of the measurement chamber of the dielectricity measurement device and of the package wall of the capsule end package without portioned material.

22. The method of claim 20, further comprising sealing the capsule end package to form the encapsulation, by joining a receiving portion of the capsule end package to a closure portion of the capsule end package before the capsule end package is introduced with the portioned material into the measurement chamber, or after the capsule end package with the portioned material has been taken out of the measurement chamber, at least part of the receiving portion and/or at least part of the closure portion forming the package wall of the capsule end package.

23. The method of claim 20, wherein the dielectricity measurement device temporarily forms an electrical measurement capacitor when the capsule end package is in the measurement position, and wherein the measuring step includes using the measurement capacitor to determine the measurement of dielectric properties.

24. The method of claim 20, wherein the dielectricity measurement device has a first coupling element for the input of microwave radiation into the measurement chamber and a second coupling element for the output of microwave radiation from the measurement chamber, the dielectricity measurement device is part of a microwave resonator for determining dielectric properties of portioned material of a capsule end package, and the dielectricity measurement device is designed to temporarily form the microwave resonator together with the temporary measurement device when the electrically conductive package wall of the capsule end package is in the measurement position, wherein the measuring step includes using the microwave resonator to determine the measurement of dielectric properties.

25. The method of claim 24, wherein the measurement chamber comprises, as a boundary, side wall portions electrically connected to the first measurement device in the measurement arrangement, the side wall portions comprising a peripherally closed wall frame with a first bottom opening and a second bottom opening, and the first measurement device and a first bottom opening of the side wall frame being movable relative to each other and temporarily form the measurement chamber by at least partially form-locking, the first measurement device and the first bottom opening of the side wall frame being moveable relative to each other and to temporarily form the dielectricity measurement device as soon as the first bottom opening is arranged directly at the first measurement device, and the package wall of the capsule end package, and the second bottom opening being moveable closer together and temporarily brought into a measurement arrangement on contact, wherein the measuring step includes using the measurement chamber and the dielectric measurement device to determine the measurement of dielectric properties.

26. The method of claim 25, wherein the dielectricity measurement device further comprises a movable cassette element containing a plurality of side wall frames connected to each other, wherein the first measurement device—constitutes part of a stationary electrically conductive shoe, the cassette element and the shoe temporarily form the measurement chamber from the first measurement device and each of the plurality of wall frames by movement of the cassette element past the part of the shoe constituting the first measurement device successively, wherein the first measurement device is formed from a cylinder arc-shaped side surface of the shoe, the cassette element is mounted rotatably and has two parallel circular rings spaced apart from each other by a plurality of radially mounted intermediate frame walls such that two adjacent intermediate frame walls and two parallel circular ring segments are connected electrically to form the wall frame, two adjacent wall frames each have a common intermediate frame wall, the shoe being arranged relative to the cassette element to electrically connect the two circular rings in the region of the first bottom openings of the wall frames, so that upon rotation of the cassette element the dielectricity measurement device is formed in each case temporarily, and the wall frames of the cassette element having second bottom openings to the outside, and the temporary measurement device and the second bottom openings move closer together and with the latter are brought temporarily into a measurement arrangement, wherein the package wall of a capsule end package is moved up to the second bottom opening of the wall frame in the revolving cassette element and brought into electrical contact with the latter, wherein the package wall together with the cassette element is moved along the stationary shoe at the same speed of rotation as the cassette element, forming a dielectricity measurement device by establishing the contact between the shoe and the first bottom opening of the wall frame in the cassette element, measurement of dielectric properties is carried out, wherein the package wall of the capsule end package is released from the second bottom opening of the wall frame in the revolving cassette element and moved away from the latter, wherein the measurement step includes using the movable cassette element and the shoe to determine a plurality of individual measurements of dielectric properties, and performing the plurality of individual measurements successively based on rotation of the cassette element and the number of wall frames present therein.

27. The method of claim 20, further comprising a series measurement device, wherein the series measurement device comprises a plurality of dielectricity measurement devices, wherein the first measurement devices of the dielectricity measurement devices are arranged on a first combination element which is designed to receive a plurality of temporary measurement devices, and wherein the package walls of the capsule end package are passed to the first combination element and the first combination element is brought into contact with the package walls of the capsule end package such that one dielectricity measurement device of the series measurement device with one package wall in the partial region of the second combination element is temporarily brought into a measurement arrangement, and wherein the measuring step includes using the series measurement device and the first combination element to determine the measurement of dielectric properties.

28. Method according to claim 27, further comprising a second combination element to receive the plurality of temporary measurement devices, the first combination element and the second combination element being movable relative to each other and a plurality of package walls arranged on the second combination element as a grid, wherein the package walls of the capsule end packages are introduced with the portioned material into the dielectricity measurement device, wherein the second combination element with the package walls of the capsule end packages is moved past the first combination element, wherein meanwhile, in a partial region of the second combination element the package walls and the second combination element are brought into contact with the first combination element by moving the second combination element, at least in one section, up to the partial region of the second combination element, and wherein the measuring step includes using the second combination element to determine the measurement of dielectric properties.

29. Method according to claim 27, wherein the first combination element is a matrix frame in which the first measurement devices of the plurality of first measurement devices are each arranged parallel and adjacent to each other, wherein the matrix frame is lowered onto a partial region of the second combination element and, at the same time, a plurality of dielectricity measurement devices of the series measurement device and a plurality of package walls in the partial region of the second combination element are simultaneously brought temporarily into measurement arrangements, and wherein the measuring step includes using the matrix frame to determine the measurement of dielectric properties.

30. Method according to claim 27, wherein the first combination element comprises a cylindrical roller frame in which the first measurement devices of the plurality of first measurement devices are each arranged adjacent to each other on the shell of a cylinder roller, wherein the cylindrical roller frame contacts the second combination element and is rolled over the second combination element with the package walls such that, at the same time, a plurality of first measurement devices of the series measurement device and a plurality of package walls in a partial region of the second combination element are temporarily brought into measurement arrangements and wherein the measuring step includes using the cylindrical roller frame to determine the measurement of dielectric properties.

31. A method for determining a mass of portioned material of a capsule end package, comprising the steps of:
determining the dielectric properties of a comparative portioned material of a known mass by the method according to claim 20;
determining dielectric properties of the portioned material by the method according to claim 20; and
calculating the mass from the results of determining dielectric properties of the comparative portioned material and of determining dielectric properties of the portioned material.

32. A method for determining the mass of portioned material of a capsule end package, comprising the steps of:
determining the dielectric properties of comparative portioned material of known mass by a the method according to a claim 24, wherein the measuring step includes determining the frequency of the resonance peak of microwaves;
determining dielectric properties of portioned material of unknown mass by the method according to claim 24, wherein the measuring step includes determining the frequency of the resonance peak of microwaves; and
calculating the mass from the results of determining dielectric properties of the comparative portioned material and of determining dielectric properties of the portioned material of unknown mass.

33. Method according to claim 32, wherein the steps of determining dielectric properties of comparative portioned material and determining dielectric properties of portioned material of unknown mass further comprise, respectively, determining an attenuation of the resonance signal of the microwaves, if the portioned material and/or the comparative portioned material and/or the gas phase in the measurement chamber show a significantly low water content.
